(19) United States
(12) Patent Application Publication
(10) Pub. No.: US 2005/0087788 A1
(43) Pub. Date: Apr. 28, 2005

(54) Semiconductor device and method for fabricating the same

(75) Inventors: Toshie Kutsunai, Shiga (JP); Takumi Mikawa, Shiga (JP); Yuji Judai, Kyoto (JP)

Correspondence Address: Jack Q. Lever, Jr.;McDERMOTT, WILL & EMERY LLP, 600 Thirteenth Street, N.W., Washington, DC, 20005-3096, US

(73) Assignee: MATSUSHITA ELECTRIC INDUSTRIAL CO., LTD.

(21) Appl. No.: 10/967,273

(22) Filed: Oct. 19, 2004

(30) Foreign Application Priority Data
Oct. 22, 2003 (JP) 2003-361649

(51) Int. Cl. H01L 21/8242; H01L 29/94

(52) U.S. Cl. 257/306; 438/244; 257/296; 257/310

(57) ABSTRACT

A semiconductor device has contact plugs each for electrically connecting a capacitor element to the source/drain region of a transistor, conductive layers formed on the contact plugs and made of titanium nitride which is a nitride only of a refractory metal, and polycrystalline conductive oxygen barrier layers each composed of a multilayer structure consisting of a titanium aluminum nitride film, an iridium film, and an iridium oxide film to prevent the diffusion of oxygen. Since the conductive layers made of titanium nitride which is low in crystal orientation is provided under the oxygen barrier films, the titanium aluminum nitride films formed as the oxygen barrier films directly on the conductive layers have a compact film structure so that the penetration of oxygen is prevented effectively.

### CROSS-REFERENCE TO RELATED APPLICATIONS

This application claims priority under 35 U.S.C. §119 on Patent Application No. 2003-361649 filed in Japan on Oct. 22, 2003, the entire contents of which are hereby incorporated by reference.

### BACKGROUND OF THE INVENTION

The present invention relates to a semiconductor device comprising a capacitor element using a metal oxide for a capacitor insulating film and a method for fabricating the same.

In recent years, a ferroelectric memory device using a planar structure having a relatively small capacity of 1 kbit to 64 kbit has started to be mass-produced and, more recently, a memory device having a stacked structure and a large capacity of 256 kbit to 4 Mbit has been becoming the main target of development.

In a stacked ferroelectric memory device, a contact plug electrically connected to a semiconductor substrate is disposed under a lower electrode composing a capacitor element with the view to reducing a cell size and thereby achieving a significant increase in the degree of integration. To implement such a stacked structure, it is necessary to prevent the contact plug from being oxidized in a thermal process for crystallizing a capacitor insulating film made of a metal oxide.

Conventionally, a structure for preventing the oxidation of the contact plug has been implemented by providing a layer of an oxygen barrier film under electrode materials, as shown in Japanese Laid-Open Patent Publication No. HEI 10-93036. Herein below, a description will be given to a conventional semiconductor device with reference to the drawings. FIG. 18 shows a cross-sectional structure of the principal portion of the semiconductor device described in the foregoing publication.

As shown in FIG. 18, a plurality of element formation regions defined by isolation films 101 of the principal surface of a semiconductor substrate 100 are formed with respective transistors each composed of a gate electrode 102 and a source/drain region 103. An interlayer insulating film 104 has been formed over the entire surface of the semiconductor substrate 100 to cover each of the transistors. In the interlayer insulating film 104, a plurality of contact plugs 105 each electrically connected to the source/drain region 103 of any of the transistors have been formed. Conductive barrier layers 106 made of iridium oxide (IrO₂) or ruthenium oxide (RuO₂) and covering the individual contact plugs 105 to prevent the diffusion of oxygen into the contact plugs 105 are formed on the interlayer insulating film 104. Capacitor elements 110 each composed of a lower electrode 107, a capacitor insulating film 108 made of a high dielectric material or a ferroelectric material such as Pb(Zr, Ti)O₃ or SrBi₂Ta₂O₉, and an upper electrode 109 are formed on the respective conductive barrier layers 106.

### SUMMARY OF THE INVENTION

The present inventors have found that the conventional semiconductor device containing the capacitor elements 110 has the following various problems.

In the conventional semiconductor device, the conductive barrier layers 106 for preventing the diffusion of oxygen (O₂) which penetrates from above the semiconductor substrate 100 and thereby preventing the upper portions of the contact plugs 105 from being oxidized in the thermal process step for the crystallization of the capacitor insulating films 108 are provided between the lower electrodes 107 and the contact plugs 105.

According to the findings made by the present inventors, however, the orientation of crystal grains in the conductive barrier layers 106 used in the conventional semiconductor device is relatively high as shown in FIG. 19A, which will be described later. If each of the crystal grains is oriented in, e.g., a direction perpendicular to the semiconductor substrate, i.e., parallel to the contact plugs 105, the upper portions of the contact plugs 105 are oxidized by oxygen (O₂) that has penetrated from above by passing through grain boundaries in the lower electrodes 107 so that a first problem of increased contact resistance is encountered. The present inventors have also found that the conductive barrier layers 106 are also easily oxidized by oxygen that has penetrated from above by passing through the grain boundaries in the lower electrodes 107.

On the other hand, there has also been a report on the conductive barrier layers 106 each having a multilayer structure consisting of a titanium aluminum nitride (TiAlN) film 106a, an iridium (Ir) film 106b, and an iridium oxide (IrOₓ) film 106c, which is for a further improvement in oxygen barrier property, as shown in FIG. 19B.

In the conductive barrier layers 106 each having such a multilayer structure, the IrOₓ films 106c and the Ir films 106b shut off the oxygen that has penetrated from above by passing through the grain boundaries in the lower electrodes 107. More specifically, the IrOₓ films 106c prevent the penetration of oxygen into the capacitor insulating films 108 during the thermal process, while the Ir films 106b prevent the oxidation of the TiAlN films 106a during the sputtering of the IrOₓ films 106c. In addition, the oxygen that has entered by passing through grain boundaries in each of the IrOₓ films 106c and the Ir films 106b forms an aluminum oxide (Al₂O₃) film on the surface of each of the TiAlN films 106a, which shuts off the penetration of oxygen into the contact plugs 105.

However, since the interlayer insulating film 104 made of silicon oxide and serving as an underlying layer for the conductive barrier films 106 has a high orientation, the conductive barrier layers 106 formed thereon are oriented preferentially to the orientation of the interlayer insulating film 104 so that grain boundaries are formed therein. Consequently, the upper portions of the contact plugs 105 are easily oxidized by oxygen that has penetrated by passing through the grain boundaries in the lower electrodes 107 and the conductive barrier layers 106 in the same manner as in the conductive barrier layers 106 each composed of a single layer shown in FIG. 19A.

In addition, the oxygen that has penetrated by passing through the respective grain boundaries in the Ir films 106b and the IrOₓ films 106c included in the conductive barrier layers 106 forms a thick oxide film on the surface of each of the TiAlN films 106a provided in the lower portions of the conductive barrier layers so that the volume of each of the TiAlN films 106a expands. Due to the expansion, the amount of oxygen laterally penetrating into the side portions of the TiAlN films 106a is particularly large as shown in FIG. 19B, so that the peripheral edge portions of the TiAlN films 106a expand more greatly than in the inner portions thereof. As a result of the volume expansion involving the greater expansion of the peripheral edge portions, a second problem is encountered that a large stress occurs in each of the conductive barrier layers 106 and, to reduce the stress, floating or delamination occurs in the conductive barrier layer 106 composed of a multilayer film structure, particularly at the interface between the TiAlN film 106a and the Ir film 106b. The floating or delamination increases the contact resistance between the contact 15 and the lower electrode 17.

It is therefore an object of the present invention to solve the foregoing conventional problems and thereby improve the oxygen barrier property of each of the conductive barrier layers having a multilayer structure, while achieving a stable contact resistance by preventing the occurrence of floating or delamination in the conductive barrier layer having the multilayer structure.

To attain the object, a first semiconductor device according to the present invention comprises: a capacitor element formed above a substrate and composed of a lower electrode, a capacitor insulating film, and an upper electrode; a conductive barrier layer formed under the lower electrode and containing a refractory metal; and a conductive layer formed under the conductive barrier layer and made of a nitride only of a refractory metal.

When the conductive barrier layer is formed on the insulating layer in the first semiconductor device, the conductive layer made of the nitride only of the refractory metal is formed in interposed relation between the conductive barrier layer and the insulating layer. Accordingly, the crystal orientation of the conductive barrier layer becomes more irregular than in the case where the conductive barrier layer is formed directly on the insulating layer and the conductive barrier layer has a more compact texture so that it prevents the passage of oxygen penetrating from above through grain boundaries in another film. This prevents the oxidation of the contact plug when the contact plug is provided under the conductive layer made of the nitride only of the refractory metal and thereby suppresses an increase in contact resistance. In addition, the volume expansion of the conductive barrier layer is also suppressed because the oxidation of the conductive barrier layer is prevented so that the deformation of the conductive barrier layer is suppressed and the floating or delamination of the conductive barrier layer is also prevented. It is to be noted that the prevent inventors have found that a nitride only of a refractory metal has an orientation lower than that of another metal.

In the first semiconductor device, at least one part of the conductive layer preferably has a polycrystalline structure or an amorphous structure. In the arrangement, the crystal structure of the conductive barrier layer formed on the conductive layer becomes compact so that the downward penetration of oxygen that has through the lower electrode or another film located above the conductive barrier layer is suppressed.

A second semiconductor device according to the present invention comprises: a capacitor element formed above a substrate and composed of a lower electrode, a capacitor insulating film, and an upper electrode; a conductive barrier layer formed under the lower electrode; and a conductive layer formed under the conductive barrier layer and containing an amorphous structure in at least one part thereof.

In the second semiconductor device, grain boundaries are not present in the conductive layer containing the amorphous structure so that the texture of the conductive layer becomes compact. Accordingly, crystal grains in the conductive barrier layer formed on the conductive layer containing the amorphous structure have smaller diameters than in the case where the conductive layer with a compact texture is not provided so that the length of the penetration path of oxygen extending from the upper portion of the conductive barrier layer to the lower portion thereof is increased. This suppresses the oxidation of the conductive barrier layer by oxygen diffused through the upper electrode and enhances the oxidation resistance of the conductive barrier layer. Consequently, the oxidation of the contact plug provided under the conductive barrier layer is prevented and the floating or delamination of the conductive barrier layer through the oxidation and volume expansion thereof is prevented so that a stable contact resistance is achieved.

In the second semiconductor device, a part of the conductive barrier layer preferably contains a refractory metal.

A third semiconductor device according to the present invention comprises: a capacitor element formed above a substrate and composed of a lower electrode, a capacitor insulating film, and an upper electrode; and a conductive barrier layer formed under the lower electrode, having an amorphous structure in at least one part thereof, and containing a refractory metal.

The third semiconductor device can achieve the same effects as achieved by the second semiconductor device and it is unnecessary to provide an additional conductive layer other than the conductive barrier layer so that the structure is simplified. In addition, a thickness increase in a direction perpendicular to the substrate of the semiconductor device resulting from the provision of the conductive layer can be prevented.

A fourth semiconductor device according to the present invention comprises: a capacitor element formed above a substrate and composed of a lower electrode, a capacitor insulating film, and an upper electrode; a conductive barrier layer formed under the lower electrode; and a conductive layer made of a refractory metal formed under the conductive barrier layer, wherein a contact area ratio of the conductive layer to the conductive barrier layer is 70% or more.

In the fourth semiconductor device, the conductive layer made of the refractory metal having a low orientation improves the film quality of the conductive barrier layer formed thereon so that the adhesion between the conductive layer and the conductive barrier layer is improved. In addition, since the contact area ratio of the conductive layer to the conductive barrier layer is 70% or more, the proportion occupied by a portion excellent in adhesion between the conductive barrier layer and the conductive layer is increased so that the conductive layer has sufficient resistance to a downward stress resulting from the deformation of the conductive barrier layer under volume expansion. In other words, the deformation of the conductive barrier layer under volume expansion is reduced by the conductive layer having a large contact area so that an increase in contact resistance is suppressed.

In the fourth semiconductor device, the conductive layer is preferably a contact plug electrically connecting the substrate and the lower electrode to each other. If the conductive layer thus serves also as the contact plug, an increase in contact resistance resulting from the deformation of the conductive barrier layer can be prevented without adding an extra constituent member.

In the fourth semiconductor device, a part of the conductive barrier layer preferably contains a refractory metal.

Preferably, the fourth semiconductor device further comprises a contact plug formed under the conductive layer to electrically connect the substrate and the lower electrode to each other.

In each of the first to fourth semiconductor devices, the conductive barrier layer preferably has an orientation more irregular than when the conductive layer is not provided under the conductive barrier layer. In the arrangement, the length of the penetration path of oxygen extending from the upper portion of the conductive barrier layer to the lower portion thereof is increased so that the oxidation of the conductive barrier layer by oxygen diffused from above is suppressed and the oxidation resistance of the conductive barrier layer is enhanced.

In each of the first to fourth semiconductor devices, an intensity ratio of a (101) peak measured by X-ray diffractometry in the conductive barrier layer preferably has a value of 3.0 or less. Since the value indicates the state in which extremely fine crystal grains are present in the conductive barrier layer, resistance to oxygen is enhanced.

A fifth semiconductor device according to the present invention comprises: a capacitor element formed above a substrate and composed of a lower electrode, a capacitor insulating film, and an upper electrode; a conductive barrier layer formed under the lower electrode; and at least two contact plugs formed under the conductive barrier layer to electrically connect the substrate and the lower electrode to each other.

In the fifth semiconductor device, the proportion occupied by the portion of the contact plug excellent in adhesion to the conductive barrier layer is increased. Since the contact plug having a larger contact area with the conductive barrier layer develops sufficient resistance to the stress under which the conductive barrier layer tends to be downwardly deformed, a stable contact resistance is achieved between the contact plug and the conductive barrier layer and between the contact plug and the lower electrode.

In each of the first to fifth semiconductor devices, the conductive barrier layer is preferably composed of a plurality of conductive barrier films stacked in layers and the one of the conductive barrier films in contact with the conductive layer is preferably made of titanium aluminum nitride.

In each of the first to fifth semiconductor devices, the conductive barrier layer is preferably composed of at least one material selected from the group consisting of ruthenium, ruthenium oxide, ruthenium silicide, ruthenium nitride, rhenium, rhenium oxide, rhenium silicide, rhenium nitride, osmium, osmium oxide, osmium silicide, osmium nitride, rhodium, rhodium oxide, rhodium silicide, rhodium nitride, iridium, iridium oxide, iridium silicide, iridium nitride, titanium aluminum, titanium aluminum silicide, titanium aluminum nitride, tantalum aluminum, tantalum aluminum silicide, tantalum aluminum nitride, platinum, and gold.

In the first semiconductor device, the conductive layer is preferably composed of at least one material selected from the group consisting of titanium nitride, tantalum nitride, tungsten nitride, and cobalt nitride.

In the second or third semiconductor device, the conductive layer is preferably composed of at least one material selected from the group consisting of titanium nitride, tantalum nitride, tungsten nitride, cobalt nitride, titanium aluminum, tantalum aluminum, tantalum, tungsten, titanium, nickel, and cobalt.

In the fourth semiconductor device, the conductive layer is preferably composed of at least one material selected from the group consisting of titanium, tantalum, tungsten, nickel, and cobalt.

In each of the first to fifth semiconductor devices, the capacitor insulating film is preferably composed of a metal oxide made of a high dielectric material or a ferroelectric material. That is, since it is necessary to perform a thermal process in an oxidizing atmosphere with respect to the metal oxide composing the capacitor insulating film after the metal oxide is deposited for the crystallization thereof, the metal oxide is suited to the present invention which enhances the oxidation resistance of the conductive barrier layer.

A first method for fabricating a semiconductor device according to the present invention comprises the steps of: burying a conductive film in an opening formed in an insulating film on a substrate to form a contact plug; forming a conductive layer made of a nitride only of a refractory metal on the insulating film such that the conductive layer is connected to the contact plug; forming a conductive barrier layer containing a refractory metal on the conductive layer; forming a lower electrode on the conductive barrier layer; forming a capacitor insulating film on the lower electrode; and forming an upper electrode on the capacitor insulating film.

In accordance with the first method for fabricating a semiconductor device, the conductive layer made of the nitride only of the refractory metal is formed on the insulating film to be connected to the contact plug and the conductive barrier layer containing the refractory metal is formed on the formed conductive layer so that the first semiconductor device according to the present invention is obtainable.

A second method for fabricating a semiconductor device according to the present invention comprises the steps of: burying a conductive film in an opening formed in an insulating film on a substrate to form a contact plug; forming, on the insulating film, a conductive layer connected to the contact plug and containing an amorphous structure in at least one part thereof; forming a conductive barrier layer on the conductive layer; forming a lower electrode on the conductive barrier layer; forming a capacitor insulating film on the lower electrode; and forming an upper electrode on the capacitor insulating film.

In accordance with the second method for fabricating a semiconductor device, the orientation of crystal grains in the conductive barrier layer varies so that the conductive barrier layer having a compact texture is formed and the second semiconductor device according to the present invention is obtainable.

A third method for fabricating a semiconductor device according to the present invention comprises the steps of: burying a conductive film in an opening formed in an insulating film on a substrate to form a contact plug; forming, on the insulating film, a conductive barrier layer connected to the contact plug and containing an amorphous structure in at least one part thereof; forming a lower electrode on the conductive barrier layer; forming a capacitor insulating film on the lower electrode; and forming an upper electrode on the capacitor insulating film.

In accordance with the third method for fabricating a semiconductor device, the conductive barrier layer connected to the contact plug and containing the amorphous structure in at least one portion thereof is formed on the insulating film so that the third semiconductor device according to the present invention is obtainable.

A fourth method for fabricating a semiconductor device according to the present invention comprises the steps of: burying a conductive film in an opening formed in an insulating film on a substrate to form a contact plug made of a refractory metal; forming a conductive barrier layer on the contact plug; forming a lower electrode on the conductive barrier layer; forming a capacitor insulating film on the lower electrode; and forming an upper electrode on the capacitor insulating film, wherein the step of forming a contact plug includes forming the contact plug such that a contact area ratio of the contact plug to the conductive barrier layer is 70% or more.

In accordance with the fourth method for fabricating a semiconductor device, the contact area ratio of the contact plug made of the refractory metal to the conductive barrier layer is 70% or more so that the fourth semiconductor device according to the present invention is obtainable.

A fifth method for fabricating a semiconductor device according to the present invention comprises the steps of: burying a conductive film in an opening formed in an insulating film on a substrate to form a contact plug; forming, on the insulating film, a conductive layer made of a refractory metal such that the conductive layer is connected to the contact plug; forming a conductive barrier layer on the conductive layer; forming a lower electrode on the conductive barrier layer; forming a capacitor insulating film on the lower electrode; and forming an upper electrode on the capacitor insulating film, wherein the step of forming a conductive layer includes forming the conductive layer such that a contact area ratio of the conductive layer to the conductive barrier layer is 70% or more.

In accordance with the fifth method for fabricating a semiconductor device, the contact area ratio of the conductive layer made of the refractory metal formed on the insulating film to be connected to the contact plug to the conductive barrier layer is 70% or more so that the fourth semiconductor device according to the present invention is obtainable.

A sixth method for fabricating a semiconductor device comprises the steps of: burying a conductive film in openings formed in an insulating film on a substrate to form at least two contact plugs; forming conductive barrier layers on the insulating film such that the conductive barrier layers are connected to the at least two contact plugs; forming a lower electrode on each of the conductive barrier layers; forming a capacitor insulating film on the lower electrode; and forming an upper electrode on the capacitor insulating film.

In accordance with the sixth method for fabricating a semiconductor device, the conductive barrier layers are formed on the insulating film to be connected to the at least two contact plugs and the lower electrode is formed on each of the formed conductive barrier layers so that the fifth semiconductor device according to the present invention is obtainable.

In the first method for fabricating a semiconductor device, the step of forming a conductive layer preferably includes forming the conductive layer containing an amorphous structure in at least one part thereof.

In the first or second method for fabricating a semiconductor device, the step of forming a conductive layer preferably includes forming the conductive layer with an irregular orientation. In the arrangement, the crystal orientation of the conductive barrier layer becomes irregular during the formation thereof so that the texture of the conductive barrier layer becomes compact and prevents the penetration of oxygen from above that has passed through grain boundaries in another film.

A seventh method for fabricating a semiconductor device according to the present invention comprises the steps of: burying a conductive film in an opening formed in an insulating film on a substrate to form a contact plug; forming a lower electrode on the insulating film such that the lower electrode is connected to the contact plug; forming a capacitor insulating film on the lower electrode; and forming an upper electrode on the capacitor insulating film, wherein the step of forming the lower electrode includes the steps of: depositing a conductive barrier layer having conductivity and a polycrystalline structure for preventing diffusion of oxygen; and performing a thermal process with respect to the deposited conductive barrier layer in an oxidizing atmosphere.

In accordance with the seventh method for fabricating a semiconductor device, the thermal process in an oxidizing atmosphere is performed with respect to the conductive barrier layer having the polycrystalline structure before the capacitor insulating film is formed. This suppresses the rapid volume expansion of the conductive barrier layer through the oxidation thereof and achieves a stable contact resistance between the contact plug and the capacitor element.

In the seventh method for fabricating a semiconductor device, the thermal process is preferably a rapid heating process.

In each of the first to seventh methods for fabricating a semiconductor device, the capacitor insulating film is preferably composed of a metal oxide made of a high dielectric material or a ferroelectric material.

### BRIEF DESCRIPTION OF THE DRAWINGS

FIGS. 1A and 1B show a semiconductor device according to a first embodiment of the present invention, of which FIG. 1A is a cross-sectional view of the principal portion thereof containing capacitor elements and transistors and FIG. 1B is a cross-sectional view diagrammatically showing conductive oxygen barrier layers and conductive layers provided between the capacitor elements and contact plugs;

FIGS. 2A to 2D are cross-sectional views showing the principal portion of the semiconductor device according to the first embodiment in the individual process steps of a fabrication method therefor;

FIG. 3 is a graph showing the relationship between the crystallization temperature of a capacitor insulating film and a contact resistance in each of the semiconductor devices according to the first and second embodiments of the present invention and a prior art semiconductor device;

FIGS. 4A and 4B show a semiconductor device according to the second embodiment of the present invention, of which FIG. 4A is a cross-sectional view of the principal portion thereof containing capacitor elements and transistors and FIG. 4B is a cross-sectional view diagrammatically showing conductive oxygen barrier layers and conductive layers provided between the capacitor elements and contact plugs;

FIGS. 5A to 5D are cross-sectional view showing the principal portion of the semiconductor device according to the second embodiment in the individual process steps of a fabrication method therefor;

FIG. 6 is a structural cross-sectional view diagrammatically showing a sample for measuring a structure of a conductive oxygen barrier layer according to the second embodiment;

FIG. 7 is a graph showing the result of a comparison made between the respective intensity ratios of (101) peaks measured by X-ray diffractometry in a conductive oxygen barrier layer under which a conductive layer is provided according to the present invention and in a conductive oxygen barrier layer under which a conductive layer is not provided;

FIGS. 8A and 8B show the relationships between conditions for depositing a conductive oxygen barrier film and the orientation of the conductive oxygen barrier layer in the semiconductor device according to the second embodiment, of which FIG. 8A is a graph showing the sputter-power dependency of the orientation of crystal grains and FIG. 8B is a graph showing the deposition-temperature dependency of the orientation of crystal grains;

FIGS. 9A and 9B show a semiconductor device according to a variation of the second embodiment, of which FIG. 9A is a cross-sectional view of the principal portion thereof containing capacitor elements and transistors and FIG. 9B is a cross-sectional view diagrammatically showing conductive oxygen barrier layers provided between the capacitor elements and contact plugs;

FIGS. 10A and 10B show a semiconductor device according to a third embodiment of the present invention, of which FIG. 10A is a cross-sectional view of the principal portion thereof containing capacitor elements and transistors and FIG. 10B is a cross-sectional view diagrammatically showing conductive oxygen barrier layers and contact plugs provided under the capacitor elements;

FIG. 11 is a graph showing the relationship between a contact area ratio of the contact plug to a lower electrode and a contact resistance in each of the semiconductor device according to the third embodiment and the prior art semiconductor device;

FIG. 12 is a graph showing the relationship between a film stress in the conductive oxygen barrier layer and the contact resistance in each of the semiconductor device according to the third embodiment and the prior art semiconductor device;

FIGS. 13A and 13B show a semiconductor device according to a variation of the third embodiment, of which FIG. 13A is a cross-sectional view of the principal portion thereof containing capacitor elements and transistors and FIG. 13B is a cross-sectional view diagrammatically showing conductive oxygen barrier layers, conductive layers, and contact plugs provided under the capacitor elements;

FIG. 14 is a cross-sectional view showing the principal portion of a semiconductor device according to a fourth embodiment of the present invention;

FIG. 15 is a graph showing the relationship between the number of contact plugs and the number of occurrences of the delamination of a conductive oxygen barrier layer in the semiconductor device according to the fourth embodiment in comparison with that in the prior art semiconductor device;

FIGS. 16A to 16C are partial cross-sectional views showing the principal portion of a semiconductor device according to a fifth embodiment of the present invention in the individual process steps of a fabrication method therefor;

FIG. 17 is a graph showing a change in contact resistance before and after annealing performed with respect to a capacitor insulating film in the semiconductor device according to the fifth embodiment in comparison with that in the prior art semiconductor device;

FIG. 18 is a structural cross-sectional view showing the principal portion of the prior art semiconductor device; and

FIG. 19A is a structural cross-sectional view diagrammatically showing a lower electrode, a conductive barrier layer, and a contact plug in the prior art semiconductor device and FIG. 19B is a structural cross-sectional view diagrammatically showing the volume expansion of the conductive barrier layer in an annealing step performed with respect to a capacitor insulating film in the prior art semiconductor device.

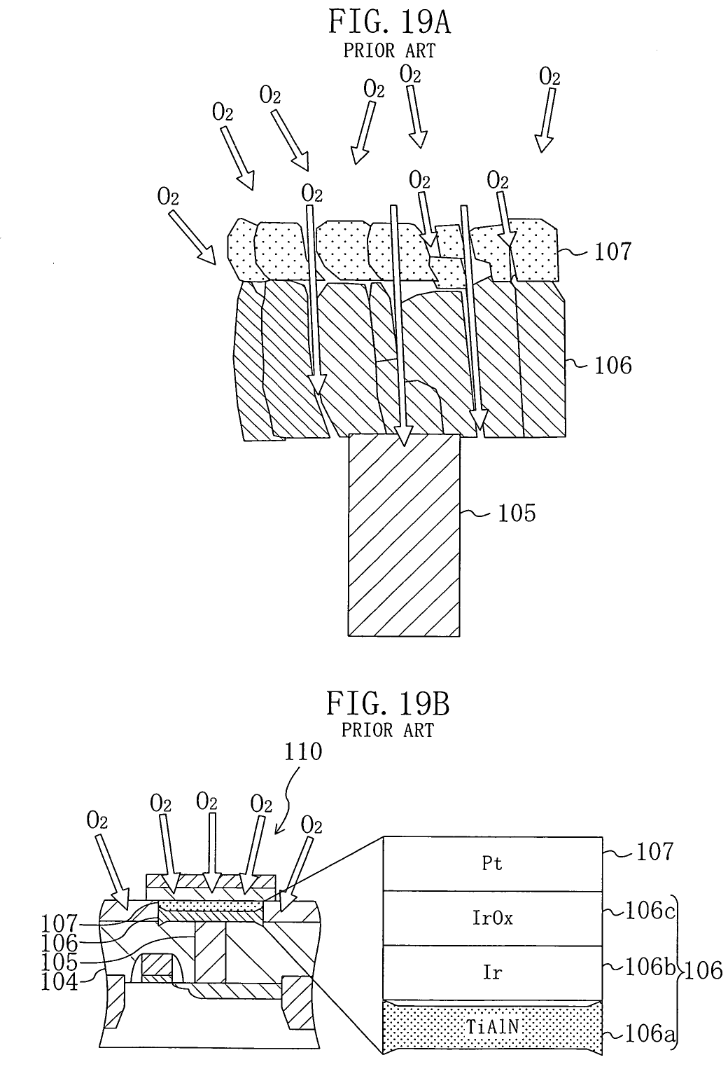

### DESCRIPTION OF THE PREFERRED EMBODIMENTS

Embodiment 1

A first embodiment of the present invention will be described with reference to the drawings.

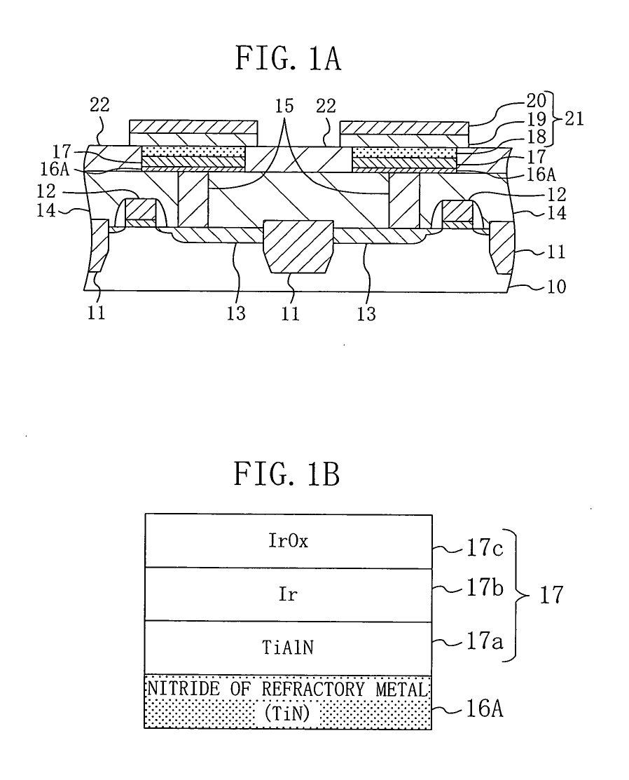

FIG. 1A shows a cross-sectional structure of the principal portion of a nonvolatile memory device as a semiconductor device according to the first embodiment.

As shown in FIG. 1A, the principal surface of a semiconductor device 10 made of, e.g., silicon (Si) is formed with a plurality of element formation regions defined by isolation films 11 such as shallow trench isolations (STI). Each of the element formation regions is formed with a transistor composed of a gate electrode 12 having a gate insulating film interposed between itself and the semiconductor substrate 10 and of a source/drain region 13. A protective insulating film 14 made of a silicon oxide or the like has been formed over the entire surface of the semiconductor substrate 10 to cover each of the transistors. In the protective insulating film 14, contact plugs 15 made of tungsten (W) or polysilicon each electrically connected to the source/drain region 13 of any of the transistors have been formed.

In each of the regions overlying the protective insulating film 14 and including the individual contact plugs 15, a conductive layer 16A made of, e.g., a polycrystalline titanium nitride (TiN) which is a nitride of a refractory metal having a thickness of about 10 nm to 50 nm and a polycrystalline conductive oxygen barrier layer 17 composed of a multilayer structure consisting of a titanium aluminum nitride (TiAlN) film 17a having a thickness of about 50 nm to 150 nm, an iridium (Ir) film 17b having a thickness of about 30 nm to 100 nm, and an iridium oxide (IrOₓ) film 17c having a thickness of about 30 nm to 100 nm which are formed successively on the conductive layer 16A to prevent the diffusion of oxygen have been formed, as shown in FIG. 1B.

The material of the conductive layers 16A is not limited to titanium nitride (TiN). The conductive layers 16A may be formed appropriately to contain at least one of, e.g., tantalum nitride (TaN), tungsten nitride (WN), and cobalt nitride (CoN).

The films composing the multilayer structure of each of the conductive oxygen barrier layers 17 are not limited to the titanium aluminum nitride film 17a, the iridium film 17b, and the iridium oxide film 17c. The conductive oxygen barrier layers 17 may be formed appropriately to contain at least one of ruthenium (Ru), ruthenium oxide (RuOₓ), ruthenium silicide (RuSiₓ), ruthenium nitride (RuNₓ), rhenium (Re), rhenium oxide (ReOₓ), rhenium silicide (ReSiₓ), rhenium nitride (ReNₓ), osmium (Os), osmium oxide (OsOₓ), osmium silicide (OsSiₓ), osmium nitride (OsNₓ), rhodium (Rh), rhodium oxide (RhOₓ), rhodium silicide (RhSiₓ), rhodium nitride (RhNₓ), iridium (Ir), iridium oxide (IrOₓ), iridium silicide (IrSiₓ), iridium nitride (IrNₓ), titanium aluminum (TiAl), titanium aluminum nitride (TiAlNₓ), titanium aluminum silicide (TiAlSiₓ), tantalum aluminum (TaAl), tantalum aluminum silicide (TaAlSiₓ), tantalum aluminum nitride (TaAlNₓ), platinum (Pt), and gold (Au).

On each of the conductive oxygen barrier layers 17, there have been formed a lower electrode made of platinum (Pt) having a thickness of about 50 nm to 150 nm, a capacitor insulating film 19 made of strontium bismuth tantalum niobate (SrBi₂(Ta_{1-y}Nb_{y})₂O₉) (where y satisfies 0≦y≦1) having a bismuth-layered perovskite structure having a thickness of 50 nm to 150 nm, and an upper electrode 20 made of platinum having a thickness of about 50 nm to 150 nm. A capacitor element 21 is composed of the lower electrode 18, the capacitor insulating film 19, and the upper electrode 20.

A buried insulating film 22 has been buried to surround each of the conductive layer 16, the conductive oxygen barrier layer 17, and the lower electrode 18.

In the semiconductor device according to the first embodiment, the conductive layers 16A made of a nitride only of a refractory metal such as titanium nitride are provided under the conductive oxygen barrier layers 17 interposed between the lower electrodes 18 of the capacitor elements 21 and the contact plugs 15 to serve as underlying layers for the conductive oxygen barrier layers 17. When deposited on the protective insulating film 14 made of silicon oxide or the like, a nitride of a refractory metal shows a low and non-uniform orientation. When the polycrystalline conductive oxygen barrier layers 17 are formed on the conductive layers 16A having a nonuniform orientation, therefore, the orientation of crystal grains in the conductive oxygen barrier layers 17 is more irregular than in the case where the conductive layers 16A are not provided. As a result, the length of the penetration path of oxygen passing through respective grain boundaries in the iridium oxide film 17c and the iridium film 17b via the upper electrode 20 to be diffused during the fabrication is increased. This suppresses the oxidation of each of the conductive oxygen barrier layers 17, improves the oxidation resistance of the conductive oxygen barrier layer 17, and thereby prevents the oxidation of the contact plug 15 formed under the conductive layer 16A. In addition, the oxidation-induced volume expansion of the titanium aluminum nitride (TiAlN) film 17a located in the lower portion of the conductive oxygen barrier layer 17 is suppressed so that the floating of the titanium aluminum nitride 17a or the delamination thereof at the interface with the iridium film 17b is prevented and a stable contact resistance is achieved between the contact plug 15 and the lower electrode 18.

The conductive layer 16A and the conductive oxygen barrier layer 17 provided between the lower electrode 18 and the contact plug 15 may also be regarded as a part of the lower electrode 18.

The material of the capacitor insulating films 19 is not limited to SrBi₂(Ta_{1-y}Nb_{y})₂O₉. It is also possible to use lead zirconium titanate (Pb(Zr_{y}Ti_{1-y})O₃), barium strontium titanate ((Ba_{y}Sr_{1-y})TiO₃), bismuth lanthanum titanate ((Bi_{y}La_{1-y})₄Ti₃O₁₂) (where y satisfies 0≦y≦1 in each of the foregoing formulae), or ditantalum pentaoxide (Ta₂O₅) to compose the capacitor insulating films 19.

Thus, according to the first embodiment, the conductive layers 16A made of titanium nitride which is a nitride only of a refractory metal are provided between the conductive oxygen barrier layers 17 and the contact plugs 15. Since a nitride of a refractory metal renders the crystal orientation of the conductive oxygen barrier layers 17 more irregular than in the case where the conductive oxygen barrier layers 17 are formed directly on the protective insulating film 14 including the contact plugs 15, the texture of the conductive oxygen barrier layers 17 becomes compact and can prevent the penetration of oxygen coming from above. This prevents the oxidation of the contact plugs 15 and thereby suppresses an increase in contact resistance. Since the oxidation of the conductive oxygen barrier layers 17 is also prevented, the volume expansion of the conductive oxygen barrier layers 17 is suppressed. As a result, the deformation of the conductive oxygen barrier layers 17 is suppressed and the floating or delamination of the conductive oxygen barrier layers 17 can also be prevented.

A description will be given herein below to a method for fabricating the semiconductor device thus constructed with reference to the drawings.

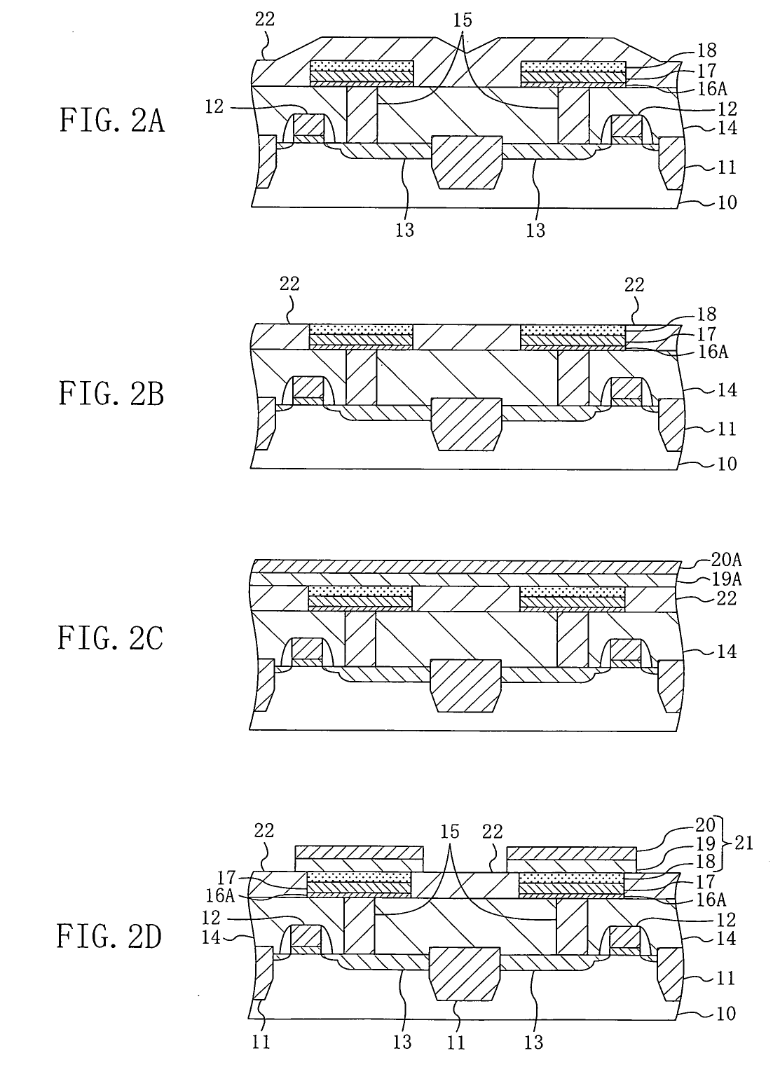

FIGS. 2A to 2D show the cross-sectional structure of the principal portion the semiconductor device according to the first embodiment in the individual process steps of the fabrication method therefor.

First, as shown in FIG. 2A, the isolation films 11 are formed selectively in the principal surface of the semiconductor substrate 10 to partition the principal surface into the plurality of element formation regions and the transistors each composed of the gate electrode 12 and the source/drain region 13 are formed in the respective element formation regions that have been defined. Then, the protective insulating film 14 is deposited by chemical vapor deposition (CVD) over the entire surface of the semiconductor substrate 10 including the transistors and the upper surface of the deposited protective insulating film 14 is planarized by chemical mechanical polishing (CMP). Subsequently, contact holes for exposing the source/drain regions 13 of the transistors are formed in the protective insulating film 14 by lithography and dry etching and the contact plugs 15 are formed in the formed contact holes by a combination of CVD and etch-back processes or a combination of CVD and CMP processes.

Then, the conductive layers 16A made of polycrystalline titanium nitride (TiN) and having sufficiently small crystal grains are formed on the protective insulating film 14 by sputtering or CVD in such a manner as to cover the respective contact plugs 15. Specifically, the titanium nitride (TiN) is formed by metal organic chemical vapor deposition (MOCVD) at a temperature of about 350° C. to 450° C. However, the method for forming the titanium nitride (TiN) is not limited to MOCVD. The titanium nitride (TiN) may also be formed by sputtering performed with a power source output of 0.5 kW to 3 kW at a temperature of 350° C.

Thereafter, titanium aluminum nitride, iridium, and iridium oxide are deposited successively on each of the conductive layers 16A by sputtering to form the conductive oxygen barrier layers 17. Subsequently, the lower electrodes 18 made of platinum are deposited by sputtering on the conductive oxygen barrier layers 17. Then, each of the conductive layers 16A, the conductive oxygen barrier layers 17, and the lower electrodes 18 is patterned into a specified configuration by dry etching using an etching gas containing chlorine (Cl₂).

Subsequently, the buried insulating film 22 made of silicon oxide (SiO₂) with a thickness of 400 nm to 600 nm is deposited on the protective insulating film 14 by CVD to cover the lower electrodes 18.

Next, as shown in FIG. 2B, the deposited buried insulating film 22 is planarized by CMP or etching to expose the lower electrodes 18.

Next, as shown in FIG. 2C, a capacitor-insulating-film forming film 19A made of SrBi₂(Ta_{1-y}Nb_{y})₂O₉ having a bismuth-layered perovskite structure with a thickness of 50 nm to 150 nm is deposited by metal organic chemical vapor deposition (MOCVD) or sputtering on the buried insulating film 22 including the lower electrodes 18. Subsequently, an upper-electrode forming film 20A made of platinum (Pt) is deposited by sputtering on the capacitor-insulating-film forming film 19A. Then, a thermal process for the crystallization of the capacitor-insulating-film forming film 19A is performed in an oxygen atmosphere at a temperature of 650° C. to 800° C. with respect to the deposited capacitor-insulating-film forming film 19A.

The thermal process for the crystallization of the capacitor-insulating-film forming film 19A may also be performed after the patterning of the upper-electrode forming film 20A and the capacitor-insulating-film forming film 19A shown in FIG. 2D.

Next, as shown in FIG. 2D, a resist pattern (not shown) covering the lower electrodes 18 is formed on the upper-electrode forming film 20A by lithography. Then, the upper-electrode forming film 20A and the capacitor-insulating-film forming film 19A are patterned by dry etching such that the upper electrodes 20 are formed from the upper-electrode forming film 20A and the capacitor insulating films 19A are formed from the capacitor-insulating-film forming film 19A. Consequently, the capacitor elements 21 each composed of the lower electrode 18, the capacitor insulating film 19, and the upper electrode 20 are formed on the conductive oxygen barrier layers 17.

Although platinum has been used as the material of each of the lower and upper electrodes 18 and 20, the electrode material is not limited to platinum. A precious metal material may also be used instead as the electrode material.

Thus, the method for fabricating a semiconductor device according to the first embodiment has formed the conductive layers 16A made of titanium nitride which is a nitride only of a refractory metal between the contact plugs 15 and the conductive oxygen barrier layers 17 provided under the lower electrodes 18 of the capacitor elements 21 so that the titanium aluminum nitride films 17a made of a nitride containing a refractory metal and located in the lower portions of the conductive oxygen barrier layers 17 have excellent adhesion.

That is, when the polycrystalline titanium aluminum nitride films 17a are deposited on the conductive layers 16A made of titanium nitride, the crystal grains composing the titanium aluminum nitride films 17a become sufficiently small so that the length of the penetration path of oxygen coming from above the upper-electrode forming film 20A is increased in the thermal process step for the crystallization of the capacitor insulating films 19. This prevents the diffusion of oxygen from the conductive oxygen barrier layers 17 to the contact plugs 15.

More specifically, since the conductive layers 16A are made of a polycrystalline nitride only of a refractory metal, the film quality thereof is compact and the polycrystalline titanium aluminum nitride films 17a formed on the conductive layers 16A are also formed to have a compact texture under the influence of the orientation of the underlying conductive layers 16A. This allows the crystal grains of each of the conductive oxygen barrier layers 17 to be formed extremely small, prevents the diffusion of oxygen penetrating from above during the thermal process for the crystallization of the capacitor insulating film 19, and thereby suppresses the oxidation of the conductive oxygen barrier layer 17.

Since the titanium aluminum film 17a has thus been formed to have a compact texture and the oxidation of the conductive oxygen barrier layer 17 including the titanium aluminum film 17a can be prevented, floating or delamination at the interface between the titanium aluminum film 17a and the iridium film 17b composing the oxygen barrier layer 17 is prevented so that a stable contact resistance is achieved between the contact plug 15 and the lower electrode 18.

Although the polycrystalline titanium nitride has been used for the conductive layer 16A, the conductive layer 16A may also be formed by using monocrystalline titanium nitride or a monocrystalline nitride only of a refractory metal. In this case, the conductive oxygen barrier layer 17 can be formed to have an orientation lower than that in the case where the conductive layer 16A is not provided and the same effects as described above are achievable.

A description will be given herein below to the result of comparing the semiconductor device according to the first embodiment with the prior art semiconductor device.

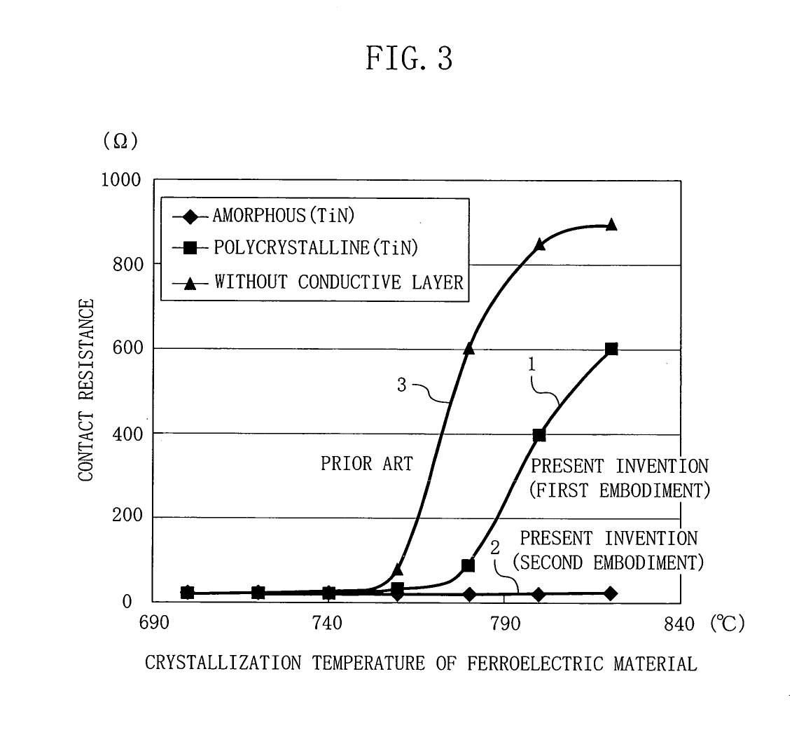

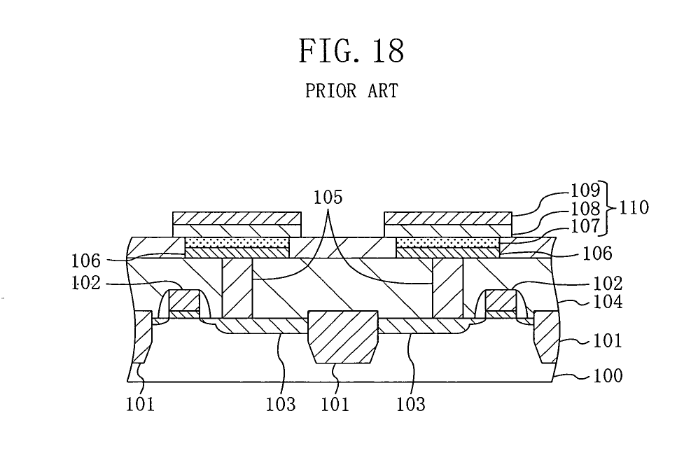

FIG. 3 shows the distribution of contact resistances between the conductive oxygen barrier layer 17 and the contact plug 15 when an oxygen process was performed with respect to the capacitor insulating film 19 at a sintering temperature (crystallization temperature) ranging from 700° C. to 820° C., in comparison with the distribution of contact resistances in the prior art semiconductor device shown in FIG. 18. The contact resistances shown herein were measured between the contact plug 15 and the capacitor element 21. In FIG. 3, the curve 1 indicates the semiconductor device according to the first embodiment, the curve 2 indicates a semiconductor device according to a second embodiment, which will be described later, and the curve 3 indicates the prior art. As indicated by the curve 1 in FIG. 3, the semiconductor device according to the first embodiment retains a contact resistance as low as about 30 Ω even at a sintering temperature of about 760° C. From the result of measurement, it will be understood that the conductive oxygen barrier layers 17 formed on the conductive layers 16A made of polycrystalline TiN according to the first embodiment can prevent oxygen diffused via the lower electrodes 18, the oxidation of the conductive oxygen barrier layers 17 has been suppressed, and a reduction in contact resistance has been achieved.

In the prior art semiconductor device indicated by the curve 3, by contrast, the contact resistance has started to increase at a sintering temperature exceeding 750° C. and is distributed in a high range of 900 Ω in the vicinity of a sintering temperature of 800° C. Therefore, it will be appreciated that, in the prior art semiconductor device, even the portions in contact with the contact plugs 105 had been oxidized through the oxidation of the conductive barrier layers 106.

Thus, in the semiconductor device according to the first embodiment and the fabrication method therefor, the conductive layers 16A made of the nitride only of a refractory metal have been formed between the conductive oxygen barrier layers 17 and the contact plugs 15 so that it becomes possible to align the crystal grains of the conductive oxygen barrier layers 17, particularly those of the nitride (e.g., TiAlN) films 17a containing a refractory metal provided in the lower portions of the conductive oxygen barrier layers 17, in an orientation which renders the TiAlN films 17a less likely to be oxidized. As a result, the deformation of the conductive oxygen barrier layers 17 is suppressed and floating or delamination resulting from the deformation can be prevented so that an increase in contact resistance is prevented reliably.

Embodiment 2

A second embodiment of the present invention will be described herein below with reference to the drawings.

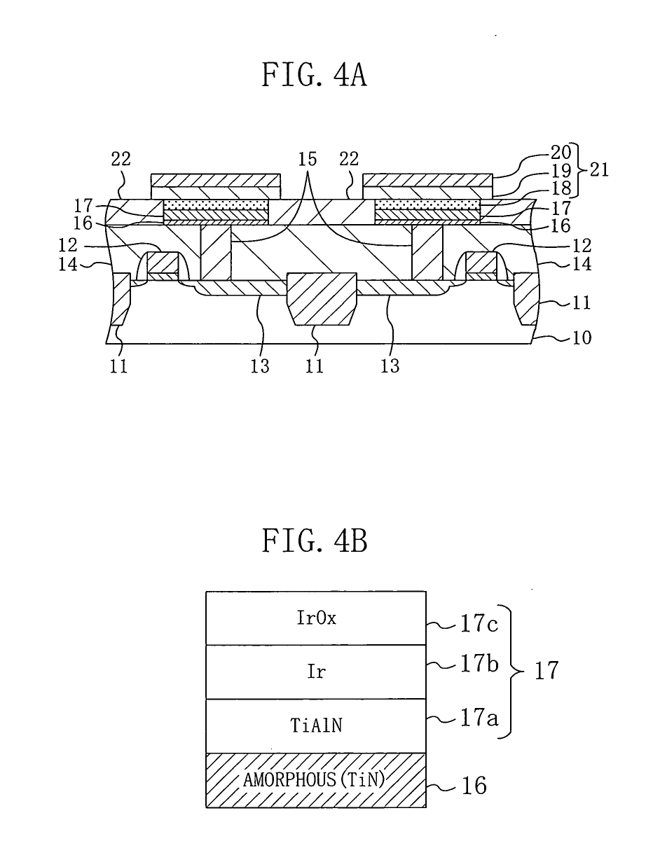

FIG. 4A shows a cross-sectional structure of the principal portion of a nonvolatile memory device as a semiconductor device according to the second embodiment. FIG. 4B is an enlarged view of the principal portion of FIG. 4A. The detailed description of the components shown in FIGS. 4A and 4B which are the same as those shown in FIG. 1 will be omitted by retaining the same reference numerals.

The second embodiment is different from the first embodiment in that a conductive layer has an amorphous structure. As shown in FIG. 4A, the structure extending from the semiconductor substrate 10 to the protective insulating film 14 is the same as in FIG. 2A according to the first embodiment so that the description thereof will be omitted.

In each of the regions overlying the protective insulating film 14 and including the individual contact plugs 15, a conductive layer 16 made of amorphous titanium nitride (TiN) having a thickness of about 10 nm to 50 nm and a polycrystalline conductive oxygen barrier layer 17 composed of a multilayer structure consisting of a titanium aluminum nitride (TiAlN) film 17a having a thickness of about 50 nm to 150 nm, an iridium (Ir) film 17b having a thickness of about 30 nm to 100 nm, and an iridium oxide (IrOₓ) film 17c having a thickness of about 30 nm to 100 nm which are formed successively on the conductive layer 16 to prevent the diffusion of oxygen have been formed, as shown in FIG. 4B.

The material of the conductive layers 16 is not limited to titanium nitride (TiN). The conductive layers 16 may be formed appropriately to contain at least one of, e.g., tantalum nitride, tungsten nitride, cobalt nitride, titanium aluminum (TiAl), tantalum aluminum (TaAl), tantalum (Ta), tungsten (W), titanium (Ti), nickel (Ni), and cobalt (Co).

The materials composing the multilayer structure of each of the conductive oxygen barrier layers 17 are not limited to titanium aluminum nitride, iridium, and iridium oxide. The conductive oxygen barrier layers 17 may be formed appropriately to contain one of the materials listed in the first embodiment, such as ruthenium (Ru) and ruthenium oxide (RuOₓ), The structure overlying the conductive oxygen barrier layers 17 inclusive thereof is the same as in the first embodiment so that the description thereof will be omitted.

In the semiconductor device according to the second embodiment thus constructed, the conductive layers 16 made of the amorphous titanium nitride are provided under the conductive oxygen barrier layers 17 formed between the lower electrodes 18 of the capacitor elements 21 and the contact plugs 15 to serve as underlying layers. When the polycrystalline conductive oxygen barrier layers 17, especially the titanium aluminum nitride films 17a in the lower portions thereof are formed, therefore, the crystal grains of the titanium aluminum nitride films 17a become smaller than in the case where the conductive layers 16 are not provided and the orientation thereof also becomes more irregular due to the morphology of the amorphous conductive layers 16 without grain boundaries.

This suppresses the oxidation of each of the conductive oxygen barrier layers 17 by oxygen diffused via the upper electrodes 20 by passing through respective grain boundaries in the iridium oxide films 17c and the iridium films 17b during the fabrication, improves the oxidation resistance of the conductive oxygen barrier layer 17, and thereby prevents the oxidation of the contact plugs 15 formed under the conductive layers 16. In addition, the oxidation-induced volume expansion of the conductive oxygen barrier layer 17, especially of the titanium aluminum nitride film 17a in the lower portion is suppressed so that floating or delamination at the interface between the titanium aluminum nitride film 17a and the iridium film 17b is prevented and a stable contact resistance is achieved between the contact plug 15 and the lower electrode 18.

The conductive layer 16 and the conductive oxygen barrier layer 17 provided between the lower electrode 18 and the contact plug 15 may also be regarded as a part of the lower electrode 18.

The material of the capacitor insulating films 19 is not limited to SrBi₂(Ta_{1-y}Nb_{y})₂O₉. It is also possible to use the ferroelectric material or high dielectric material listed in the first embodiment, such as lead zirconium titanate (Pb(Zr_{y}T_{1-y})O₃) or barium strontium titanate ((Ba_{y}Sr_{1-y})TiO₃) (where y satisfies 0≦y≦1) to compose the capacitor insulating film 19.

A description will be given herein below to a method for fabricating the semiconductor device thus constructed with reference to the drawings. However, the detailed description of the same components as used in the first embodiment will be omitted.

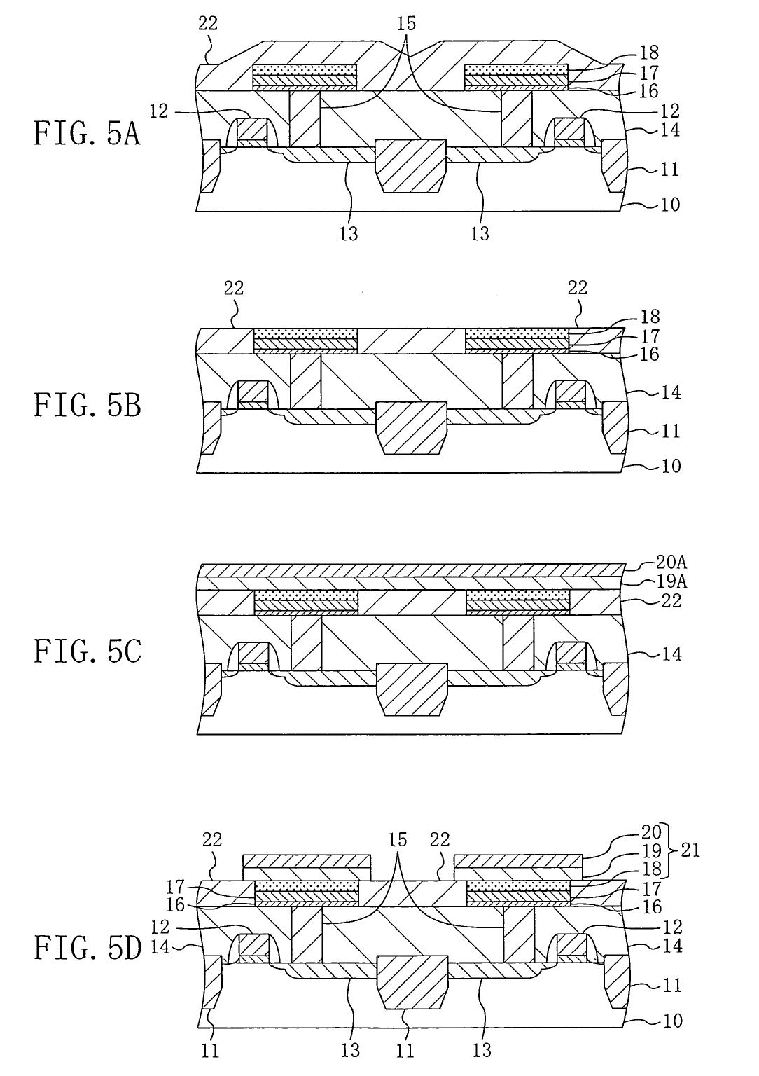

FIGS. 5A to 5D show the cross-sectional structure of the principal portion of the semiconductor device according to the second embodiment in the individual process steps of the fabrication method therefor. The description of the components shown in FIGS. 5A to 5D which are the same as those shown in FIG. 2 will be omitted by retaining the same reference numerals.

First, as shown in FIG. 5A, the transistors, the protective insulating film 14, and the contact plugs 15 are formed successively on the principal surface of the semiconductor substrate 10.

Then, the conductive layers 16 made of the amorphous titanium nitride (MOCVD-TiN) are formed on the protective insulating film 14 to cover the respective contact plugs 15 by metal organic chemical vapor deposition (MOCVD) at a temperature of about 350° C. to 450° C. by using, e.g., tetrakis dimethyl amino titanium (TDMAT) as an organic metal raw material. The method for depositing the amorphous titanium nitride is not limited to MOCVD. The amorphous titanium nitride may also be deposited by sputtering performed with a power source output of 4 kW to 10 kW at a temperature of 350° C.

Thereafter, titanium aluminum nitride, iridium, and iridium oxide are deposited successively on each of the conductive layers 16 to form the conductive oxygen barrier layers 17 and the lower electrodes 18. Then, each of the conductive layers 16, the conductive oxygen barrier layers 17, and the lower electrodes 18 is patterned into a specified configuration.

Subsequently, the buried insulating film 22 made of silicon oxide (SiO₂) and having a thickness of 400 nm to 600 nm is deposited on the protective insulating film 14 by CVD to cover the lower electrodes 18.

The subsequent process steps shown in FIGS. 5B to 5D are the same as those shown in FIGS. 2B to 2D so that the description thereof will be omitted.

Thus, in accordance with the method for fabricating the semiconductor device according to the second embodiment, the amorphous conductive layers 16 are formed between the conductive oxygen barrier layers 17 located under the lower electrodes 18 and the contact plugs 15 so that crystal grains composing each of the polycrystalline conductive oxygen barrier layers 17 are reduced in size to have a compact texture so that the oxidation resistance of the conductive oxygen barrier layer 17 is improved. This allows the suppression of the oxidation of the conductive oxygen barrier layer 17, prevents the floating or delamination of the conductive oxygen barrier layer 17, and thereby achieving a stable contact resistance between the contact plug 15 and the lower electrode 18.

A description will be given herein below to the result of comparing the semiconductor device according to the second embodiment and the prior art semiconductor device.

As indicated by the curve 2 of FIG. 3, the semiconductor device according to the second embodiment retains a contact resistance as low as about 30 Ω even at a sintering temperature exceeding 800° C. From the result of measurement, it will be understood that the conductive oxygen barrier layers 17 formed on the conductive layers 16 made of amorphous TiN according to the second embodiment can prevent oxygen diffused via the lower electrodes 18, the oxidation of the conductive oxygen barrier layer 17 has been suppressed, and a reduction in contact resistance has been achieved. By contrast, the prior art semiconductor device indicated by the curve 3 shows a resistance value as high as 900 Ω at a sintering temperature in the vicinity of 800° C. and it will be appreciated that even the portions in contact with the contact plugs 105 have been oxidized.

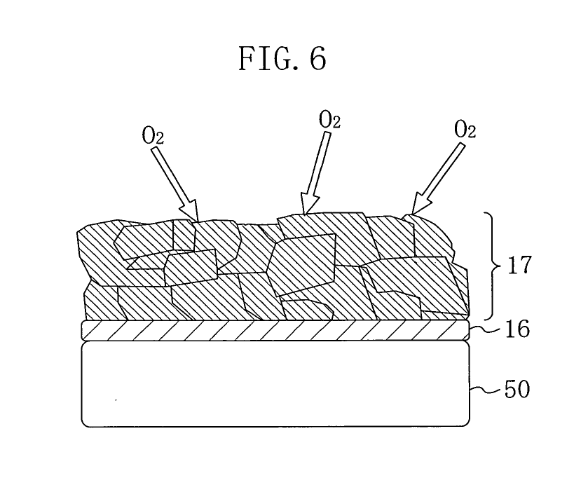

FIG. 6 diagrammatically shows a cross-sectional structure of a sample for measuring a structure of the conductive oxygen barrier layer according to the second embodiment.

As shown in FIG. 6, the conductive layer 16 made of the amorphous titanium nitride with a thickness of 10 nm to 50 ml is deposited on a substrate 50 by CVD and the conductive oxygen barrier layer 17 made of titanium aluminum nitride with a thickness of 50 nm to 150 nm is deposited on the deposited conductive layer 16. As can be seen from FIG. 6, the amorphous conductive layer 16 has no grain boundary and therefore renders the crystal grains composing the conductive oxygen barrier layer 17 extremely fine so that the texture of the conductive oxygen barrier layer 17 becomes compact. As a result, the crystal grains of the conductive oxygen barrier layer 17 become smaller than in the case where the conductive layer 16 is not formed and the orientation thereof becomes more irregular. This increases the length of the penetration path of oxygen, suppresses the oxidation of the conductive oxygen barrier layer 17 by oxygen diffused via the upper electrode 20, and greatly improves an oxygen barrier property for the contact plug 15 as well as the oxygen barrier property of the conductive oxygen barrier layer 17.

The following is the result of measuring the orientation of crystal grains in each of the conductive oxygen barrier layers 17 according to the second embodiment.

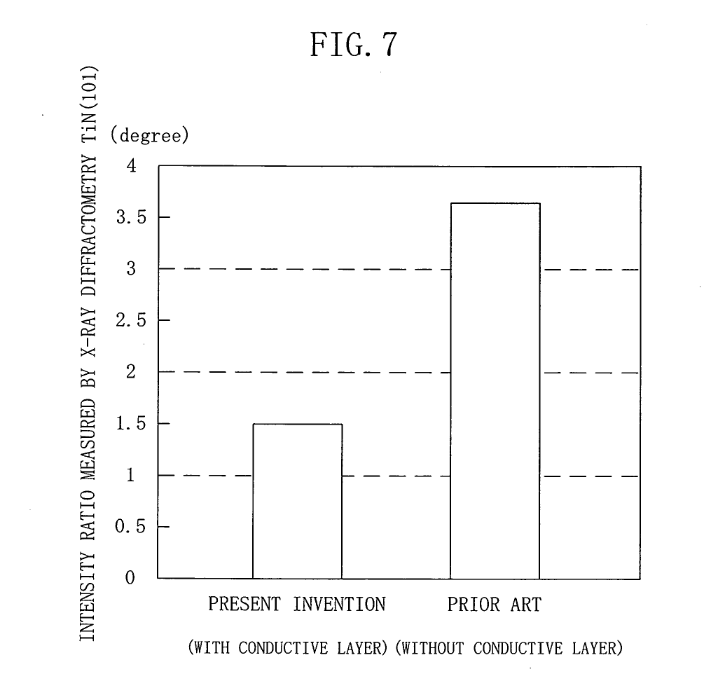

FIG. 7 shows the result of a comparison made between the respective intensity ratios of (101) peaks measured by X-ray diffractometry in the conductive oxygen barrier layer 17 under which a conductive layer is provided and in the conductive oxygen barrier layer under which a conductive layer is not provided. As can be seen from FIG. 7, the conductive oxygen barrier layer according to the second embodiment is deposited by CVD over the conductive layer 16 serving as an underlying layer, which contains numerous amorphous layers and is inferior in crystallinity. In this case, the intensity ratio of the (101) peak measured by X-ray diffractometry shows a value as low as 1.5.

By contrast, the intensity ratio of the (101) peak measured by X-ray diffractometry in the prior art semiconductor device in which the conductive layer 16 is not provided shows a value as high as 3.6, which indicates a high orientation, i.e., uniform crystal grains.

Thus, the second embodiment allows each of the conductive oxygen barrier layers 17 to have an orientation which renders it less likely to be oxidized by using the amorphous conductive layer 16 as an underlying layer for the conductive oxygen barrier layer 17. That is, since the crystal grains of the conductive oxygen barrier layer 17 are extremely small, the probability that the grain boundaries of the crystal grains composing the conductive oxygen barrier layer 17 extend through the barrier layer 17 from the top surface to the back surface thereof is lowered. This prevents the diffusion of oxygen penetrating from above the capacitor element 21 into the contact plug 15 during the thermal process for the crystallization of the capacitor insulating film 19 and also suppresses the oxidation of the conductive oxygen barrier layer 17. As a result, the floating or delamination of the conductive oxygen barrier layer 17 is prevented and a stable contact resistance is achieved between the contact plug 15 and the lower electrode 18.

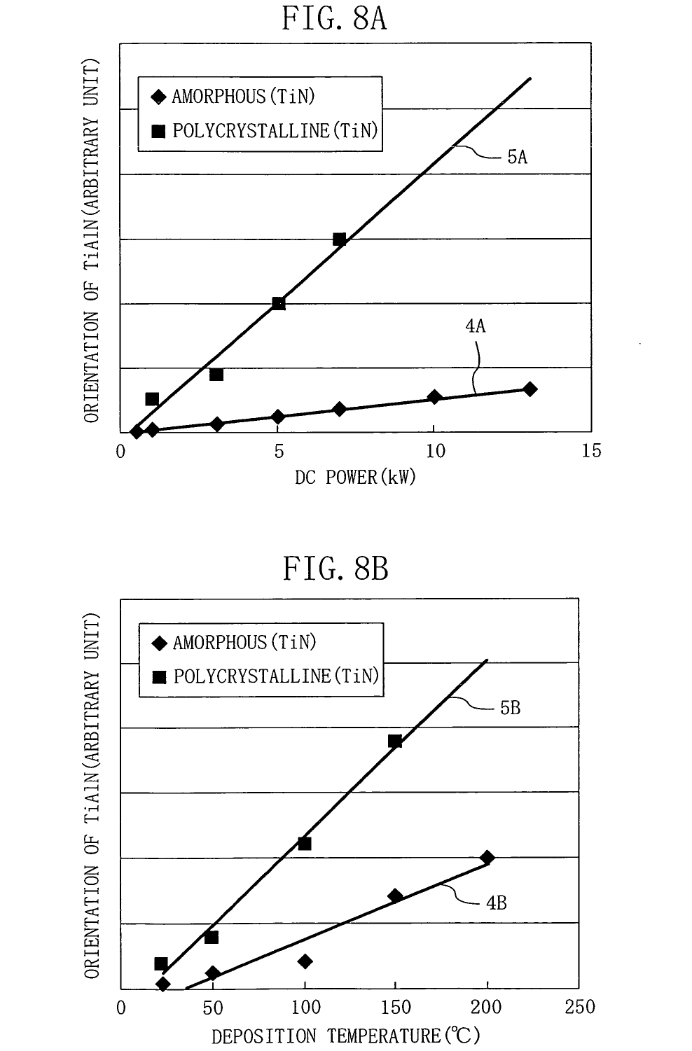

FIG. 8A shows the deposition-temperature dependency of the orientation of a TiAlN film composing the conductive oxygen barrier layer 17 when it is deposited by sputtering on the amorphous conductive layer 16 serving as an underlying layer for the conductive oxygen barrier layer 17. FIG. 8B shows the DC-power dependency of the orientation of the TiAlN film. In FIGS. 8A and 8B, the direct lines 4A and 4B show the case where the conductive layer according to the second embodiment is provided as the underlying layer, while the direct lines 5A and 5B show the case where a polycrystalline conductive layer is provided as the underlying layer for comparison. The ordinate of each of the graphs represents the intensity ratio measured by X-ray diffractometry.

From FIG. 8A, it can be seen that the orientation of the TiAlN film is gradually increased as the DC power is increased. The tendency is particularly prominent in the polycrystalline conductive layer 16A provided as the underlying layer. Accordingly, the DC power is preferably not more than 3 kw. From FIG. 8B, on the other hand, it can be seen that the orientation is also gradually increased by raising the deposition temperature. In this case also, the tendency is particularly prominent in the polycrystalline conductive layer provided as the underlying layer. Accordingly, the deposition temperature is preferably in the range of a room temperature to about 150° C.

Thus, it can be seen from FIGS. 8A and 8B that the orientation of the TiAlN film deposited on the conductive layer made of TiN and serving as the underlying layer varies depending on the crystal condition of the conductive layer. It can also be seen that the orientation of the TiAlN film also varies depending on conditions for the deposition. From the results of measurement, therefore, it will be understood that the orientation of the TiAlN film composing the conductive oxygen barrier layer 17 can be determined by properly controlling the conditions for the deposition of the TiAlN film depending on the crystalline condition of the conductive layer containing a refractory metal and composing the underlying layer, whereby the TiAlN film which is low in orientation, i.e., resistant to the penetration of oxygen is deposited.

Variation of Embodiment 2

A variation of the second embodiment will be described herein below with reference to the drawings.

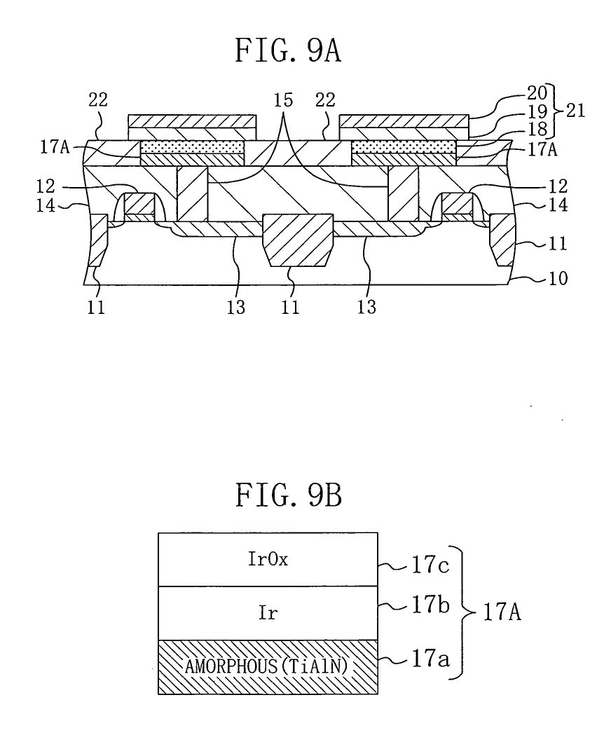

FIG. 9A shows a cross-sectional structure of the principal portion of a nonvolatile memory device as a semiconductor device according to the variation of the second embodiment. The description of the components shown in FIG. 9A which are the same as those shown in FIG. 4A will be omitted by retaining the same reference numerals.

As shown in FIG. 9A, the semiconductor device according to the present variation is constructed such that only conductive oxygen barrier layers 17A are provided between the lower electrodes 18 composing the capacitor elements 21 and the contact plugs 15. As shown in FIG. 9B, each of the conductive oxygen barrier layers 17A is composed of a multilayer structure consisting of an amorphous TiAlN film 17a having a thickness of about 50 nm to 150 nm, an iridium (Ir) film 17b having a thickness of about 30 nm to 100 nm, and an iridium oxide (IrOₓ) film 17c having a thickness of about 30 nm to 100 nm which are formed upwardly in succession.

The amorphous TiAlN films 17a according to the present variation are deposited by reactive sputtering using a target material containing titanium (Ti) and aluminum (Al) and a gas mixture of argon (Ar) and nitrogen (N₂).

According to the present variation, the TiAlN film 17a located in the lower portion of each of the conductive oxygen barrier layers 17A provided between the contact plugs 15 and the lower electrodes 18 of the capacitor elements 21 has an amorphous structure so that the Ir film 17b and the IrOₓ film 17c deposited on the TiAlN film 17a are influenced by the orientation of the TiAlN film 17a in the lower portion. This allows the formation of the conductive oxygen barrier layer 17A having a low orientation and a compact structure.

As a result, it becomes possible to obtain the conductive oxygen barrier layer 17A which is excellent in oxidation resistance and resistant to delamination without providing a conductive layer other than the conductive oxygen barrier layer 17A. This achieves a reduction in the number of process steps and limits the height of the resulting semiconductor device.

Embodiment 3

A third embodiment of the present invention will be described herein below with reference to the drawings.

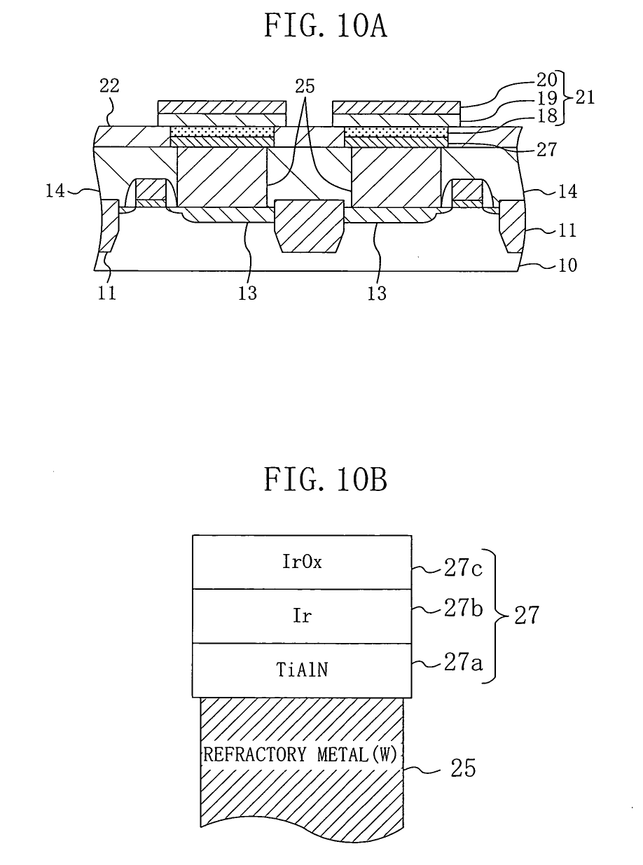

FIG. 10A shows a cross-sectional structure of the principal portion of a nonvolatile memory device as a semiconductor device according to the third embodiment. The description of the components shown in FIG. 10A which are the same as those shown in FIG. 1A will be omitted by retaining the same reference numerals.

As shown in FIG. 10A, the semiconductor device according to the third embodiment has contact plugs 25 each formed in the protective insulating film 14 on the semiconductor substrate 10 to provide electrical connection between the source/drain region 13 of a transistor in the semiconductor substrate 10 and the lower electrode 18 of the capacitor element 21 and also has conductive oxygen barrier layers 27 each formed between the contact plug 25 and the lower electrode 18. In the third embodiment, conductive layers made of an amorphous or polycrystalline nitride of a refractory metal are not provided between the contact plugs 25 and the conductive oxygen barrier layers 27.

As shown in the enlarged view of FIG. 10B, each of the contact plugs 25 is made of, e.g., tungsten (W) and the diameter of the contact plug 25 has been set to a dimension substantially equal to the diameter of the lower surface of the conductive oxygen barrier layer 27.

Each of the conductive oxygen barrier layers 27 is composed of a multilayer structure consisting of a polycrystalline TiAlN film 27a having a thickness of about 50 nm to 150 nm, an iridium (Ir) film 27b having a thickness of about 30 nm to 100 nm, and an iridium oxide (IrOₓ) film 27c having a thickness of about 30 nm to 100 nm, which are formed upwardly in succession.

According to the third embodiment, the contact plugs 25 are substantially entirely opposed to the lower electrodes 18 via the conductive oxygen barrier layers 27 so that the contact plugs 25 have sufficient resistance to a downward stress (indentation stress) exerted thereon when the conductive oxygen barrier layers 27 located thereover are oxidized to be deformed.

Even when the peripheral edge portions of the conductive oxygen barrier layers 27 undergo volume expansion through the oxidation thereof during the thermal process performed with respect to the capacitor insulating films 19 for the crystallization thereof, therefore, the downwardly bent deformation of the conductive oxygen barrier layers 27 resulting from the stress can be suppressed by the contact plugs 25 each having a large diameter. This prevents the floating or delamination of the conductive oxygen barrier layers 27 and thereby prevents an increase in the contact resistance between the contact plug 25 and the capacitor element 21.

When the diameter of the contact plug is small as in the prior art semiconductor device, the contact area between the TiAlN film (conductive oxygen barrier film) and the contact plug is small, while the contact area between the conductive oxygen barrier film and silicon oxide (protective insulating film) is large, so that the TiAlN film 27a is prone to delamination when a room temperature is restored due to the difference in thermal expansion coefficient between silicon oxide and the TiAlN film. In the third embodiment, however, the lower surface of the TiAlN film 27a is substantially entirely in contact with tungsten having a small thermal expansion coefficient difference so that the delamination of the TiAlN film 27a when a room temperature is restored is prevented.

In addition, the TiAlN film 27a is influenced by the orientation in the surface of the contact plug 25 made of tungsten when the TiAlN film 27a of the conductive oxygen barrier layer 27 is formed so that it becomes possible to form the conductive oxygen barrier layer 27 having a low orientation and a compact structure.

As a result, the conductive oxygen barrier layer 27 excellent in oxidation resistance and resistant to delamination can be obtained without providing conductive layer other than the conductive oxygen barrier layer 27.

A description will be given herein below to the result of comparing the relationship between the contact resistance and the contact area ratio of the contact plug to the lower electrode in the semiconductor device according to the third embodiment with the relationship therebetween in the prior art semiconductor device.

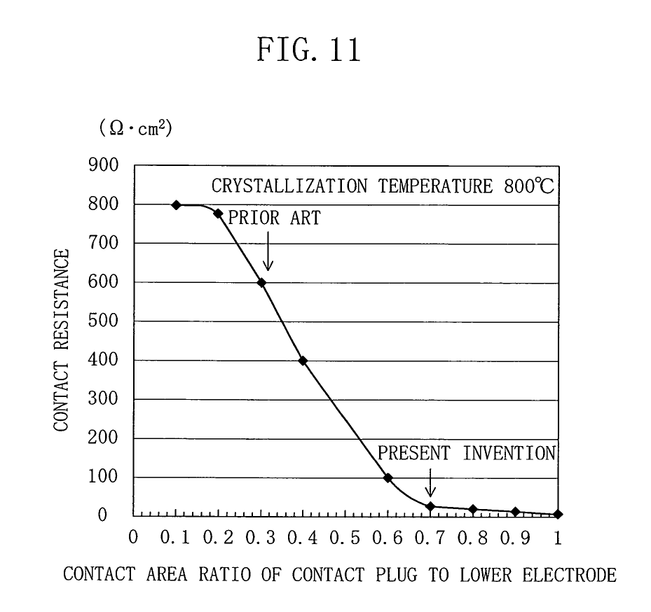

FIG. 11 shows the relationship between the contact resistance and the contact area ratio of the contact plug to the lower electrode in each of the semiconductor device according to the third embodiment and the prior art semiconductor device. It is assumed herein that the lower electrode contains the conductive oxygen barrier film. The sintering temperature for the ferroelectric material was adjusted to 800° C. and the contact resistance was measured between the conductive oxygen barrier layer 27 and the capacitor element 21. The contact area ratio of the contact plug 25 to the lower electrode 18 was adjusted to 0.7.

As shown in FIG. 11, the semiconductor device according to the third embodiment has a contact resistance as low as 30 Ω when the contact area ratio of the contact plug 25 to the lower electrode 18 is 0.7 or more. This is because the floating or delamination of the conductive barrier layer 27 resulting from the deformation of the conductive oxygen barrier layer 27 has been prevented and it will be appreciated that an increase in contact resistance has been suppressed.

By contrast, the prior art semiconductor device shows a contact resistance as high as 600 Ω conceivably because the conductive barrier layer 106 is deformed into a downwardly bent configuration by an expansion stress resulting from the oxidation of the peripheral edge portion thereof and consequently undergoes floating or delamination, which leads to partial faulty conduction.

A description will be given next to the result of comparing the relationship between a film stress in the conductive oxygen barrier layer 27 and the contact resistance between the contact plug 25 and the capacitor element 21 in the semiconductor device according to the third embodiment with the relationship therebetween in the prior art semiconductor device.

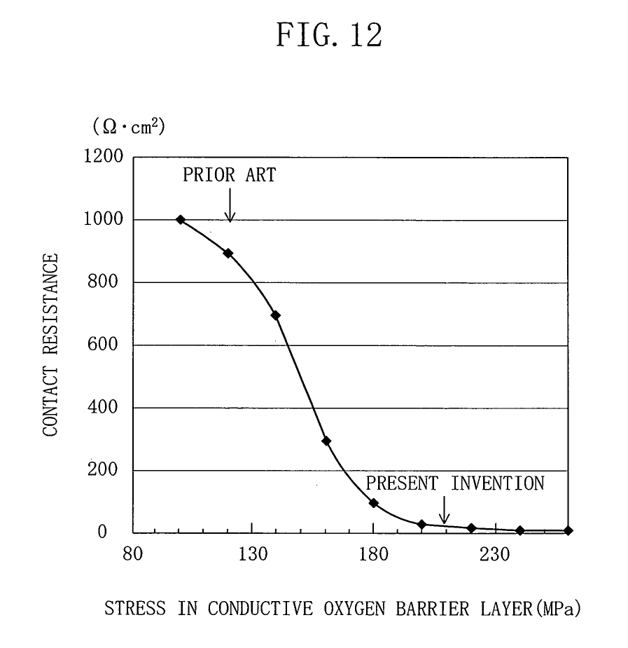

FIG. 12 shows the relationship between the film stress in the conductive oxygen barrier layer and the contact resistance between the contact plug and the capacitor element in each of the semiconductor device according to the third embodiment and the prior art semiconductor device. Each of the samples used herein was obtained by forming a plurality of contact plugs having different diameters in an insulating film formed on a semiconductor substrate and forming conductive oxygen barrier layers on the respective contact plugs. Each of the measurement values shown in FIG. 12 indicates an average of respective values obtained from the plurality of samples.

As shown in FIG. 12, the contact resistances started to abruptly lower when the film stress becomes about 160 MPa or more and a substantially stable low contact resistance is obtainable when the film stress is 210 MPa or more. This is because the resistance of the contact plug 25 to the downward indentation stress of the conductive oxygen barrier layer 27 increases when the contact area ratio of the contact plug 25 to the lower electrode 18 via the conductive oxygen barrier layer 27 becomes 0.7 or more so that the deformation preventing effect is enhanced. Judging from the relationship shown in FIG. 12, a material having a film stress of 210 MPa or more is used preferably for the conductive oxygen barrier layer 27. For example, aluminum tantalum nitride (TaAlN), titanium silicon nitride (TiSiN), tantalum silicon nitride, or the like is used preferably.

Variation of Embodiment 3

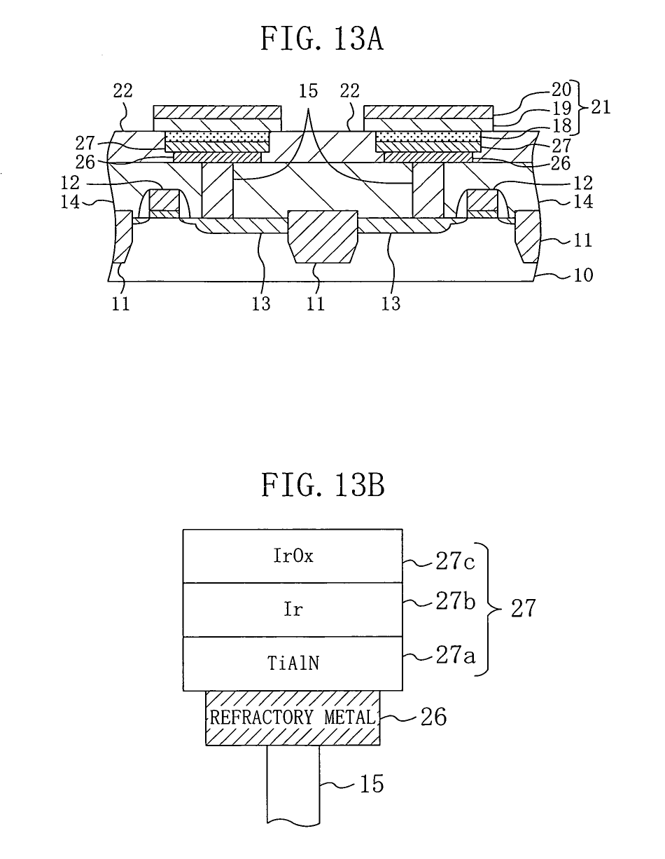

A variation of the third embodiment will be described herein below with reference to FIG. 13.

Each of FIGS. 13A and 13B shows a cross-sectional structure of the principal portion of a nonvolatile memory device as a semiconductor device according to the variation of the third embodiment. The description of the components shown in FIGS. 13A and 13B which are the same as those shown in FIGS. 10A and 10B will be omitted by retaining the same reference numerals.

As shown in FIGS. 13A and 13B, the semiconductor device according to the present variation has the contact plugs 15 made of tungsten (W) or polysilicon formed in the protective insulating film 14 and conductive layers 26 made of a refractory metal such as tungsten (W) and formed between the contact plugs 15 and the conductive oxygen barrier layers 27. The material of the conductive layers 26 is not limited to tungsten (W). Another refractory metal such as titanium (Ti), tantalum (Ta), nickel (Ni), or cobalt (Co) may also be used instead.

As shown in FIG. 13B, each of the conductive layers 26 made of a refractory metal is formed to have a contact area ratio of 70% or more to the conductive oxygen barrier layer 27.

Since the present variation has set the contact area ratio of the conductive layer 26 to the lower electrode 18 via the conductive oxygen barrier layer 27 to 0.7 or more, the conductive layer 26 has enhanced resistance to the downward indentation stress of the conductive oxygen barrier layer 27 and the deformation preventing effect is increased. Even when the peripheral edge portion of the conductive oxygen barrier layer 27 undergoes volume expansion through the oxidation thereof during the thermal process performed with respect to the capacitor insulating film 19 for the crystallization thereof, the downwardly bent deformation of the conductive oxygen barrier layer 27 resulting from the stress can be suppressed with the conductive layer 26.

In addition, the TiAlN film 27a is influenced by the orientation in the surface of the conductive layer 26 made of tungsten when the TiAlN films 27a of the conductive oxygen barrier layer 27 is formed so that it becomes possible to form the conductive oxygen barrier layer 27 having a low orientation and a compact structure. This prevents the floating or delamination of the conductive oxygen barrier layer 27 and thereby prevents an increase in the contact resistance between the contact plug 25 and the capacitor element 21.

Since the diameter of the contact plug 15 need not be increased, an increase in chip area is prevented.

Embodiment 4

A fourth embodiment of the present invention will be described herein below with reference to the drawings.

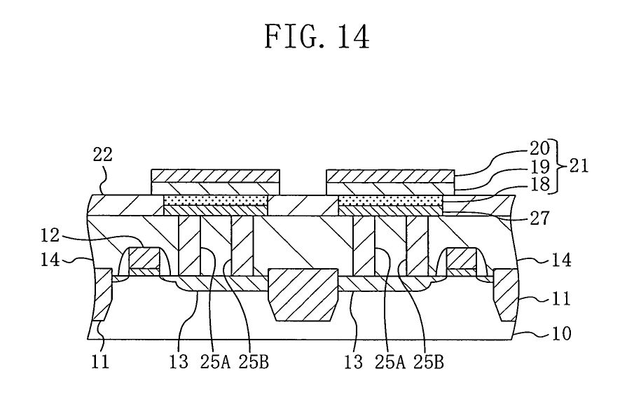

FIG. 14 shows a cross-sectional structure of the principal portion of a nonvolatile memory device as a semiconductor device according to the fourth embodiment. The description of the components shown in FIG. 14 which are the same as those shown in FIG. 10A will be omitted by retaining the same reference numerals.

In the fourth embodiment, the source/drain region 13 of each of the transistors and the lower electrode 18 of the capacitor element 21 are connected in parallel to each other with two contact plugs 25A and 25B made of a refractory metal or polysilicon. In addition, an amorphous conductive layer is not provided between each of the contact plugs 25A and 25B and the conductive oxygen barrier layer 27. The contact plugs 25A and 25B need not necessarily be arranged in parallel relation.

By thus providing the two contact plugs 25A and 25B, the total contact area of the contact plugs 25A and 25B with the conductive oxygen barrier layers 27 is increased compared with the case where only one contact plug having a normal thickness is provided so that the contact plugs 25A and 25B have sufficient resistance to the downward indentation stress when the conductive oxygen barrier layers 27 located thereon are oxidized to be deformed.

Even when the peripheral edge portions of the conductive oxygen barrier layers 27 undergo volume expansion through the oxidation thereof during the thermal process performed with respect to the capacitor insulating films 19 for the crystallization thereof, therefore, the downwardly bent deformation of the conductive oxygen barrier layers 27 resulting from the stress can be suppressed with the two contact plugs 25A and 25B. This prevents the floating or delamination of the condcutive oxygen barrier layers 27 and thereby prevents an increase in the contact resistance between each of the contact plugs 25A and 25B and the capacitor element 21.

A description will be given to the result of comparing the relationship between the number of contact plugs and the number of occurrences of the delamination of the conductive oxygen barrier layers in the semiconductor device according to the fourth embodiment with the relationship therebetween in the prior art semiconductor device. Here, a thermal process in an oxygen atmosphere at 800° C., which is the sintering temperature (crystallization temperature) for the ferroelectric material composing the capacitor insulating film 19, was performed with respect to samples in which only one contact plug was provided and in which two to five contact plugs were provided.

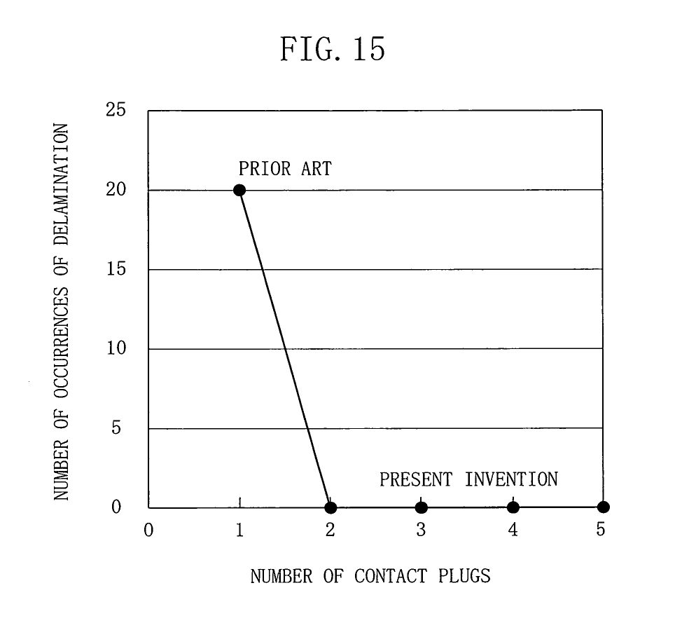

From FIG. 15, it can be seen that the conductive oxygen barrier layers 27 of the semiconductor device according to the present embodiment underwent no delamination due to the two or more contact plugs provided therein.

By contrast, when only one contact plug having a normal diameter was provided as in the prior art semiconductor device, delamination easily occurred because of the relatively low contact area ratio of the contact plug to the conductive oxygen barrier layer so that the number of the occurrences of delamination was over 20. The total number of samples used herein was 500,000.

Thus, according to the fourth embodiment, at least two contact plugs of the conventional size are disposed preferably as the contact plug 25A and the like for connecting the lower electrodes 18 and the transistors to each other in consideration of the miniaturization of memory cells.

More preferably, the number of contact plugs is determined such that the total contact area ratio of the plurality of contact plugs, including the contact plug 25A, is 70% or more in the same manner as in the third embodiment.

Embodiment 5

A fifth embodiment of the present invention will be described herein below with reference to the drawings.

The fifth embodiment is characterized in that a thermal process is performed with respect to the conductive oxygen barrier layers prior to the thermal process for the crystallization of the capacitor insulating films.

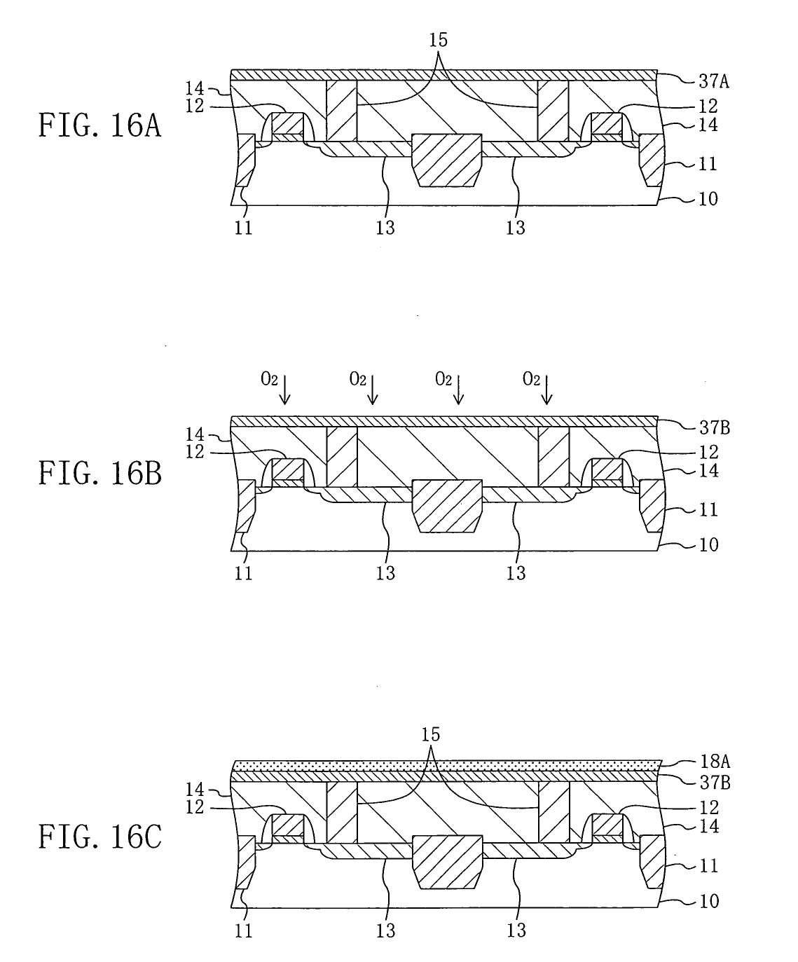

FIGS. 16A to 16C show the cross-sectional structures of a semiconductor device according to the fifth embodiment in the individual process steps of a fabrication method therefor. The description of the components shown in FIGS. 16A to 16C which are the same as those shown in FIG. 1A will be omitted by retaining the same reference numerals. A description will be given to the steps prior to and inclusive of the step of forming a lower-electrode forming layer and the step of forming a conductive-oxygen-barrier-layer forming layer.

First, as shown in FIG. 16A, the isolation films 11 are formed selectively in the principal surface of the semiconductor substrate 10 to partition the principal surface into a plurality of element formation regions and the transistors each composed of the gate electrode 12 and the source/drain region 13 are formed in the respective element formation regions that have been defined. Then, the protective insulating film 14 is deposited by CVD over the entire surface of the semiconductor substrate 10 including the transistors and the upper surface of the deposited protective insulating film 14 is planarized by CMP. Subsequently, contact holes for exposing the source/drain regions 13 of the transistors are formed in the protective insulating film 14 by lithography or dry etching and the contact plugs 15 are formed in the formed contact holes by CVD and etch-back processes or by CVD or CMP processes.

Thereafter, titanium aluminum nitride (TiAlN), iridium (Ir), and iridium oxide (IrOₓ) are deposited successively by sputtering over the protective insulating film 14 including the contact plugs 15 to form a conductive-oxygen-barrier-layer forming layer 37A.

Next, as shown in FIG. 16B, a rapid thermal process is performed with respect to the conductive-oxygen-barrier-layer forming layer 37A in an oxygen atmosphere at a temperature of about 450° C. to 550° C. for 1 to 2 minutes, thereby forming a conductive-oxygen-barrier-layer forming layer 37B that has been thermally processed.

Next, as shown in FIG. 16C, a lower-electrode forming film 18A made of platinum is deposited by sputtering on the conductive-oxygen-barrier-layer forming layer 37B.

Thereafter, the lower-electrode forming film 18A and the conductive-oxygen-barrier-layer forming layer 37B are patterned by dry etching and the buried insulating film, the capacitor insulating films, and the upper electrodes are formed successively to obtain capacitor elements.

Thus, the fifth embodiment performs the rapid thermal process for oxidation in an oxidizing atmosphere with respect to at least the upper portion of the conductive-oxygen-barrier-layer forming layer 37A to form the conductive-oxygen-barrier-layer forming layer 37B prior to the deposition of the capacitor insulating films, specifically prior to the thermal process performed in an oxidizing atmosphere for the crystallization of the ferroelectric material composing the capacitor insulating film. Since the conductive-oxygen-barrier-layer forming layer 37B has preliminarily been thermally processed, the volume expansion thereof resulting from rapid oxidation is suppressed even during oxygen annealing performed at a relatively high temperature for the crystallization of the capacitor insulating films so that an increase in the contact resistance between the contact plug 15 and the capacitor element resulting from the floating or delamination of the conductive-oxygen-barrier-layer forming layer 37B is prevented reliably.

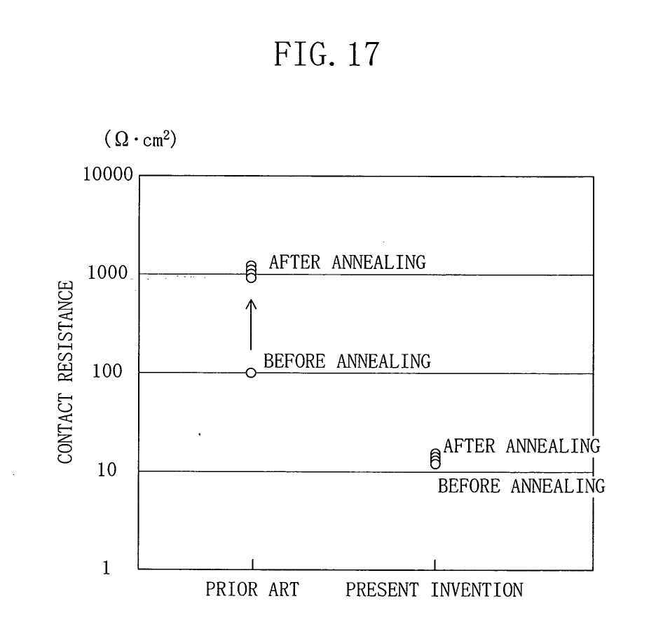

Referring to FIG. 17, a description will be given herein below to the result of comparing a change in contact resistance before and after annealing performed with respect to the capacitor insulating film in the semiconductor device according to the fifth embodiment with the change in the prior art semiconductor device. The thermal process was performed in an oxidizing atmosphere at 800° C., which is the sintering temperature for the ferroelectric material composing the capacitor insulating film, and the contact resistance was measured between the conductive oxygen barrier layer and the capacitor element.

As shown in FIG. 17, the contact resistance in the semiconductor device according to the present embodiment was about 30 Ω even before or after the annealing process performed with respect to the capacitor insulating film. This indicates that the oxidation-induced volume expansion of the conductive oxygen barrier layer resulting from the annealing process performed with respect to the capacitor insulating film was prevented by the rapid thermal process performed in an oxidizing atmosphere with respect to the conductive oxygen barrier layer prior to the annealing process performed with respect to the capacitor insulating film.

In the prior art semiconductor device, by contrast, the contact resistance before annealing was 100 Ω and the contact resistance after annealing was as high as 1000 Ω. A conceivable reason for this is that expansion stress resulting from the oxidation of the peripheral edge portion of the conductive oxygen barrier layer caused the downwardly bend deformation of the conductive oxygen barrier layer and the resulting floating or delamination of the conductive oxygen barrier layer caused partial faulty conduction.

In the fifth embodiment, oxidation-induced volume expansion as described in the conventional embodiment does not occur in the uppermost layer of the TiAlN film since the rapid thermal process for the conductive-oxygen-barrier-layer forming layer 37A was performed in an oxidizing atmosphere at a relatively low temperature of 450° C. to 550° C.

It is also possible in each of the third to fifth embodiments to form an amorphous conductive layer between the contact plug and the conductive oxygen barrier layer and provide a conductive oxygen barrier layer composed of relatively small crystal grains on the formed conductive layer, in the same manner as in the second embodiment.

Thus, the semiconductor device according to the present invention and the fabrication method therefor have the effect of preventing the conductive oxygen barrier layer for preventing the diffusion of oxygen from being deformed by oxygen and the effect of achieving a stable contact resistance so that they are useful as a semiconductor device comprising a capacitor element using a metal oxide for the capacitor insulating film thereof and a fabrication method therefor.

1. A semiconductor device comprising:
a capacitor element formed above a substrate and composed of a lower electrode, a capacitor insulating film, and an upper electrode;
a conductive barrier layer formed under the lower electrode and containing a refractory metal; and
a conductive layer formed under the conductive barrier layer and made of a nitride only of a refractory metal.

2. The semiconductor device of claim 1, wherein at least one part of the conductive layer has a polycrystalline structure or an amorphous structure.

3. The semiconductor device of claim 1, wherein the conductive barrier layer has an orientation more irregular than when the conductive layer is not provided under the conductive barrier layer.

4. The semiconductor device of claim 1, wherein an intensity ratio of a (101) peak measured by X-ray diffractometry in the conductive barrier layer has a value of 3.0 or less.

5. The semiconductor device of claim 1, wherein the conductive barrier layer is composed of a plurality of conductive barrier films stacked in layers and the one of the conductive barrier films in contact with the conductive layer is made of titanium aluminum nitride.

6. The semiconductor device of claim 1, wherein the conductive barrier layer is composed of at least one material selected from the group consisting of ruthenium, ruthenium oxide, ruthenium silicide, ruthenium nitride, rhenium, rhenium oxide, rhenium silicide, rhenium nitride, osmium, osmium oxide, osmium silicide, osmium nitride, rhodium, rhodium oxide, rhodium silicide, rhodium nitride, iridium, iridium oxide, iridium silicide, iridium nitride, titanium aluminum, titanium aluminum silicide, titanium aluminum nitride, tantalum aluminum, tantalum aluminum silicide, tantalum aluminum nitride, platinum, and gold.

7. The semiconductor device of claim 1, wherein the conductive layer is composed of at least one material selected from the group consisting of titanium nitride, tantalum nitride, tungsten nitride, and cobalt nitride.

8. The semiconductor device of claim 1, wherein the capacitor insulating film is composed of a metal oxide made of a high dielectric material or a ferroelectric material.

9. A semiconductor device comprising:
a capacitor element formed above a substrate and composed of a lower electrode, a capacitor insulating film, and an upper electrode;
a conductive barrier layer formed under the lower electrode; and
a conductive layer formed under the conductive barrier layer and containing an amorphous structure in at least one part thereof.

10. The semiconductor device of claim 9, wherein a part of the conductive barrier layer contains a refractory metal.

11. The semiconductor device of claim 9, wherein the conductive barrier layer has an orientation more irregular than when the conductive layer is not provided under the conductive barrier layer.

12. The semiconductor device of claim 9, wherein an intensity ratio of a (101) peak measured by X-ray diffractometry in the conductive barrier layer has a value of 3.0 or less.

13. The semiconductor device of claim 9, wherein the conductive barrier layer is composed of a plurality of conductive barrier films stacked in layers and the one of the conductive barrier films in contact with the conductive layer is made of titanium aluminum nitride.

14. The semiconductor device of claim 9, wherein the conductive barrier layer is composed of at least one material selected from the group consisting of ruthenium, ruthenium oxide, ruthenium silicide, ruthenium nitride, rhenium, rhenium oxide, rhenium silicide, rhenium nitride, osmium, osmium oxide, osmium silicide, osmium nitride, rhodium, rhodium oxide, rhodium silicide, rhodium nitride, iridium, iridium oxide, iridium silicide, iridium nitride, titanium aluminum, titanium aluminum silicide, titanium aluminum nitride, tantalum aluminum, tantalum aluminum silicide, tantalum aluminum nitride, platinum, and gold.

15. The semiconductor device of claim 9, wherein the conductive layer is composed of at least one material selected from the group consisting of titanium nitride, tantalum nitride, tungsten nitride, cobalt nitride, titanium aluminum, tantalum aluminum, tantalum, tungsten, titanium, nickel, and cobalt.

16. The semiconductor device of claim 9, wherein the capacitor insulating film is composed of a metal oxide made of a high dielectric material or a ferroelectric material.

17. A semiconductor device comprising:
a capacitor element formed above a substrate and composed of a lower electrode, a capacitor insulating film, and an upper electrode; and
a conductive barrier layer formed under the lower electrode, having an amorphous structure in at least one part thereof, and containing a refractory metal.

18. The semiconductor device of claim 17, wherein the conductive barrier layer has an orientation more irregular than when the conductive layer is not provided under the conductive barrier layer.

19. The semiconductor device of claim 17, wherein an intensity ratio of a (101) peak measured by X-ray diffractometry in the conductive barrier layer has a value of 3.0 or less.

20. The semiconductor device of claim 17, wherein the conductive barrier layer is composed of a plurality of conductive barrier films stacked in layers and the one of the conductive barrier films in contact with the conductive layer is made of titanium aluminum nitride.

21. The semiconductor device of claim 17, wherein the conductive barrier layer is composed of at least one material selected from the group consisting of ruthenium, ruthenium oxide, ruthenium silicide, ruthenium nitride, rhenium, rhenium oxide, rhenium silicide, rhenium nitride, osmium, osmium oxide, osmium silicide, osmium nitride, rhodium, rhodium oxide, rhodium silicide, rhodium nitride, iridium, iridium oxide, iridium silicide, iridium nitride, titanium aluminum, titanium aluminum silicide, titanium aluminum nitride, tantalum aluminum, tantalum aluminum silicide, tantalum aluminum nitride, platinum, and gold.

22. The semiconductor device of claim 17, wherein the conductive layer is composed of at least one material selected from the group consisting of titanium nitride, tantalum nitride, tungsten nitride, cobalt nitride, titanium aluminum, tantalum aluminum, tantalum, tungsten, titanium, nickel, and cobalt.

23. The semiconductor device of claim 17, wherein the capacitor insulating film is composed of a metal oxide made of a high dielectric material or a ferroelectric material.

24. A semiconductor device comprising:
a capacitor element formed above a substrate and composed of a lower electrode, a capacitor insulating film, and an upper electrode;
a conductive barrier layer formed under the lower electrode; and
a conductive layer made of a refractory metal formed under the conductive barrier layer, wherein
a contact area ratio of the conductive layer to the conductive barrier layer is 70% or more.

25. The semiconductor device of claim 24, wherein the conductive layer is a contact plug electrically connecting the substrate and the lower electrode to each other.

26. The semiconductor device of claim 24, wherein a part of the conductive barrier layer contains a refractory metal.

27. The semiconductor device of claim 24, further comprising a contact plug formed under the conductive layer to electrically connect the substrate and the lower electrode to each other.

28. The semiconductor device of claim 24, wherein the conductive barrier layer has an orientation more irregular than when the conductive layer is not provided under the conductive barrier layer.

29. The semiconductor device of claim 24, wherein an intensity ratio of a (101) peak measured by X-ray diffractometry in the conductive barrier layer has a value of 3.0 or less.

30. The semiconductor device of claim 24, wherein the conductive barrier layer is composed of a plurality of conductive barrier films stacked in layers and the one of the conductive barrier films in contact with the conductive layer is made of titanium aluminum nitride.

31. The semiconductor device of claim 24, wherein the conductive barrier layer is composed of at least one material selected from the group consisting of ruthenium, ruthenium oxide, ruthenium silicide, ruthenium nitride, rhenium, rhenium oxide, rhenium silicide, rhenium nitride, osmium, osmium oxide, osmium silicide, osmium nitride, rhodium, rhodium oxide, rhodium silicide, rhodium nitride, iridium, iridium oxide, iridium silicide, iridium nitride, titanium aluminum, titanium aluminum silicide, titanium aluminum nitride, tantalum aluminum, tantalum aluminum silicide, tantalum aluminum nitride, platinum, and gold.

32. The semiconductor device of claim 24, wherein the conductive layer is composed of at least one material selected from the group consisting of titanium, tantalum, tungsten, nickel, and cobalt.

33. The semiconductor device of claim 24, wherein the capacitor insulating film is composed of a metal oxide made of a high dielectric material or a ferroelectric material.

34. A semiconductor device comprising:
a capacitor element formed above a substrate and composed of a lower electrode, a capacitor insulating film, and an upper electrode;
a conductive barrier layer formed under the lower electrode; and
at least two contact plugs formed under the conductive barrier layer to electrically connect the substrate and the lower electrode to each other.

35. The semiconductor device of claim 34, wherein the conductive barrier layer is composed of a plurality of conductive barrier films stacked in layers and the one of the conductive barrier films in contact with the contact plugs is made of titanium aluminum nitride.

36. The semiconductor device of claim 34, wherein the conductive barrier layer is composed of at least one material selected from the group consisting of ruthenium, ruthenium oxide, ruthenium silicide, ruthenium nitride, rhenium, rhenium oxide, rhenium silicide, rhenium nitride, osmium, osmium oxide, osmium silicide, osmium nitride, rhodium, rhodium oxide, rhodium silicide, rhodium nitride, iridium, iridium oxide, iridium silicide, iridium nitride, titanium aluminum, titanium aluminum silicide, titanium aluminum nitride, tantalum aluminum, tantalum aluminum silicide, tantalum aluminum nitride, platinum, and gold.

37. The semiconductor device of claim 34, wherein the capacitor insulating film is composed of a metal oxide made of a high dielectric material or a ferroelectric material.

38. A method for fabricating a semiconductor device, the method comprising the steps of:
burying a conductive film in an opening formed in an insulating film on a substrate to form a contact plug;
forming a conductive layer made of a nitride only of a refractory metal on the insulating film such that the conductive layer is connected to the contact plug;
forming a conductive barrier layer containing a refractory metal on the conductive layer;
forming a lower electrode on the conductive barrier layer;
forming a capacitor insulating film on the lower electrode; and
forming an upper electrode on the capacitor insulating film.

39. The method of claim 38, wherein the step of forming a conductive layer includes forming the conductive layer containing an amorphous structure in at least one part thereof.

40. The method of claim 38, wherein the step of forming a conductive layer includes forming the conductive layer with an irregular orientation.

41. The method of claim 38, wherein the capacitor insulating film is composed of a metal oxide made of a high dielectric material or a ferroelectric material.

42. A method for fabricating a semiconductor device, the method comprising the steps of:
burying a conductive film in an opening formed in an insulating film on a substrate to form a contact plug;
forming, on the insulating film, a conductive layer connected to the contact plug and containing an amorphous structure in at least one part thereof;
forming a conductive barrier layer on the conductive layer;
forming a lower electrode on the conductive barrier layer;
forming a capacitor insulating film on the lower electrode; and
forming an upper electrode on the capacitor insulating film.

43. The method of claim 42, wherein the step of forming a conductive layer includes forming the conductive layer with an irregular orientation.

44. The method of claim 42, wherein the capacitor insulating film is composed of a metal oxide made of a high dielectric material or a ferroelectric material.

45. A method for fabricating a semiconductor device, the method comprising the steps of:
burying a conductive film in an opening formed in an insulating film on a substrate to form a contact plug;
forming, on the insulating film, a conductive barrier layer connected to the contact plug and containing an amorphous structure in at least one part thereof;
forming a lower electrode on the conductive barrier layer;
forming a capacitor insulating film on the lower electrode; and
forming an upper electrode on the capacitor insulating film.

46. The method of claim 45, wherein the capacitor insulating film is composed of a metal oxide made of a high dielectric material or a ferroelectric material.

47. A method for fabricating a semiconductor device, the method comprising the steps of:
burying a conductive film in an opening formed in an insulating film on a substrate to form a contact plug made of a refractory metal;
forming a conductive barrier layer on the contact plug;
forming a lower electrode on the conductive barrier layer;
forming a capacitor insulating film on the lower electrode; and
forming an upper electrode on the capacitor insulating film, wherein
the step of forming a contact plug includes forming the contact plug such that a contact area ratio of the contact plug to the conductive barrier layer is 70% or more.

48. The method of claim 47, wherein the capacitor insulating film is composed of a metal oxide made of a high dielectric material or a ferroelectric material.

49. A method for fabricating a semiconductor device, the method comprising the steps of:
burying a conductive film in an opening formed in an insulating film on a substrate to form a contact plug;
forming, on the insulating film, a conductive layer made of a refractory metal such that the conductive layer is connected to the contact plug;
forming a conductive barrier layer on the conductive layer;
forming a lower electrode on the conductive barrier layer;
forming a capacitor insulating film on the lower electrode; and
forming an upper electrode on the capacitor insulating film, wherein the step of forming a conductive layer includes forming the conductive layer such that a contact area ratio of the conductive layer to the conductive barrier layer is 70% or more.

50. The method of claim 49, wherein the capacitor insulating film is composed of a metal oxide made of a high dielectric material or a ferroelectric material.

51. A method for fabricating a semiconductor device, the method comprising the steps of:
burying a conductive film in openings formed in an insulating film on a substrate to form at least two contact plugs;
forming conductive barrier layers on the insulating film such that the conductive barrier layers are connected to the at least two contact plugs;
forming a lower electrode on each of the conductive barrier layers;
forming a capacitor insulating film on the lower electrode; and
forming an upper electrode on the capacitor insulating film.

52. The method of claim 51, wherein the capacitor insulating film is composed of a metal oxide made of a high dielectric material or a ferroelectric material.

53. A method for fabricating a semiconductor device, the method comprising the steps of:
burying a conductive film in an opening formed in an insulating film on a substrate to form a contact plug;
forming a lower electrode on the insulating film such that the lower electrode is connected to the contact plug;
forming a capacitor insulating film on the lower electrode; and
forming an upper electrode on the capacitor insulating film, wherein
the step of forming the lower electrode includes the steps of:
depositing a conductive barrier layer having conductivity and a polycrystalline structure for preventing diffusion of oxygen; and
performing a thermal process with respect to the deposited conductive barrier layer in an oxidizing atmosphere.

54. The method of claim 53, wherein the thermal process is a rapid heating process.

55. The method of claim 53, wherein the capacitor insulating film is composed of a metal oxide made of a high dielectric material or a ferroelectric material.
